(19) United States
(12) Patent Application Publication
(10) Pub. No.: US 2024/0268193 A1
(43) Pub. Date: Aug. 8, 2024

(54) WINDOW, DISPLAY DEVICE INCLUDING THE SAME, AND METHOD OF MANUFACTURING THE SAME

(71) Applicant: SAMSUNG DISPLAY CO., LTD., YONGIN-SI (KR)

(72) Inventors: JONGHYEON CHOI, Yongin-si (KR); GWANGTEAK LEE, Yongin-si (KR)

(21) Appl. No.: 18/432,177

(22) Filed: Feb. 5, 2024

(30) Foreign Application Priority Data
Feb. 7, 2023 (KR) 10-2023-0016346

(51) Int. Cl. H10K 59/80; B32B 3/30; B32B 15/08; B32B 15/09; B32B 17/10; B32B 27/08; B32B 27/28; B32B 27/36; H10K 102/00

(52) U.S. Cl. CPC H10K 59/873; B32B 3/30; B32B 15/08; B32B 15/09; B32B 17/10; B32B 27/08; B32B 27/281; B32B 27/36; B32B 2457/20; H10K 2102/311

(57) ABSTRACT

A window for a display device includes a substrate has a pattern portion and a non-pattern portion. The pattern portion includes first groove patterns recessed from an upper surface of the substrate and second groove patterns recessed from a lower surface of the substrate and alternately arranged with the first groove patterns. The non-pattern portion is adjacent to the pattern portion. In addition, a plurality of first filling layers are disposed in the first groove patterns, and a second filling layer covers the first filling layers. A plurality of third filling layers are disposed in the second groove patterns, and a fourth filling layer covers the third filling layers. A height of the pattern portion is less than a height of the non-pattern portion.

### CROSS-REFERENCE TO RELATED APPLICATIONS

This U.S. non-provisional patent application claims priority under 35 U.S.C. § 119 of Korean Patent Application No. 10-2023-0016346, filed on Feb. 7, 2023, the entire contents of which are hereby incorporated by reference.

### BACKGROUND

### 1. Technical Field

One or more embodiments described herein relate to a window, a display device including the same, and a method of manufacturing the same.

### 2. Description of the Related Art

Display devices are used in various multimedia devices. Examples include television sets, mobile phones, tablet computers, and game consoles. Recently, various types of flexible display devices which are foldable or bendable have been developed. The flexible display devices are modifiable in shape in various ways by being foldable, rollable, or bendable, and have portability. Flexible display devices include foldable or bendable display panels and windows. However, the windows of the flexible display devices may be deformed by folding or bending operations or easily damaged by external shock.

### SUMMARY

One or more embodiments described herein provide a window for a display device having excellent folding properties and improved surface quality.

One or more embodiments described herein provide a display device including the aforementioned window and which has improved viewability.

One or more embodiments described herein provide a method of manufacturing a window having excellent folding properties, improved surface quality, and improved process reliability.

These and/or other improvements provided by the embodiments described herein will become apparent in view of the following description.

An embodiment of the inventive concept provides a window including a substrate that includes an upper surface and a lower surface facing the upper surface, and includes a pattern portion including first groove patterns recessed from the upper surface and second groove patterns recessed from the lower surface and alternately arranged with the first groove patterns, and a non-pattern portion adjacent to the pattern portion, first filling layers each disposed in the first groove patterns, a second filling layer covering the first filling layers, third filling layers each disposed in the second groove patterns, and a fourth filling layer covering the third filling layers, wherein a height of the pattern portion is smaller than a height of the non-pattern portion.

In an embodiment, the upper surface may include a first upper surface in the non-pattern portion and a second upper surface in the pattern portion, and the second upper surface may be disposed to be more recessed than the first upper surface.

In an embodiment, the second filling layer may be disposed in a step formed between the first upper surface and the second upper surface.

In an embodiment, the second upper surface may be recessed by about 14 μm to about 20 μm from a plane to which the first upper surface extends.

In an embodiment, the second filling layer may continuously extend from the first filling layer disposed on one side among the first filling layers to the first filling layer disposed on the other side among the first filling layers.

In an embodiment, the lower surface may include a first lower surface in the non-pattern portion and a second lower surface in the pattern portion, and the second lower surface may be disposed to be more recessed than the first lower surface, and the fourth filling layer may be disposed in a step formed between the first lower surface and the second lower surface.

In an embodiment, the non-pattern portion may include a first non-pattern portion and a second non-pattern portion spaced apart in a second direction crossing the first direction with the pattern portion therebetween, the upper surface may include a (1-1)-th upper surface included in the first non-pattern portion, a (1-2)-th upper surface included in the second non-pattern portion, and second upper surfaces included in the pattern portion, first inner surfaces of the substrate defining the first groove patterns may include a (1-1)-th inner surface extending from the (1-1)-th upper surface, a (1-2)-th inner surface extending from the (1-2)-th upper surface, and a (1-3)-th inner surfaces extending from the second upper surfaces, and the (1-1)-th and (1-2)-th inner surfaces may each protrude further upward than the (1-3)-th inner surfaces.

In an embodiment, the first groove patterns may each provide first recessed spaces, a plane to which a portion of the (1-1)-th inner surface protruding further than the (1-3)-th inner surface, a portion of the (1-2)-th inner surface protruding further than the (1-3)-th inner surfaces, and the second upper surfaces extend may provide a second recessed space, and the first recessed spaces and the second recessed space may be formed as a single-body space.

In an embodiment, the second filling layer may cover the second upper surfaces, at least a portion of the (1-1)-th inner surface protruding further than the (1-3)-th inner surfaces, and at least a portion of the (1-2)-th inner surface protruding further than the (1-3)-th inner surfaces.

In an embodiment, the first to fourth filling layers may each have substantially the same refractive index as the substrate.

In an embodiment, the window may further include at least one additional filling layer disposed on the second filling layer and covering the second filling layer.

In an embodiment, the first groove patterns and the second groove patterns may each extend in a first direction, and the first groove patterns and the second groove patterns may alternately be arranged in a second direction crossing the first direction, and the substrate may be folded or bent with respect to an imaginary axis extending in the first direction.

In an embodiment of the inventive concept, a display device includes a display module including a folding region folded with respect to an imaginary axis extending in one direction and a non-folding region adjacent to the folding region, and a window disposed on the display module. The window includes a substrate that includes an upper surface and a lower surface facing the upper surface, and includes a pattern portion including first groove patterns recessed from the upper surface and second groove patterns recessed from the lower surface and alternately arranged with the first groove patterns, and a non-pattern portion adjacent to the pattern portion, first filling layers each disposed in the first groove patterns, a second filling layer covering the first filling layers, third filling layers each disposed in the second groove patterns, and a fourth filling layer covering the third filling layers, and a height of the pattern portion is smaller than a height of the non-pattern portion.

In an embodiment, the display device may further include a protection film disposed below the display module, and a support member disposed below the protection film.

In an embodiment of the inventive concept, a method of manufacturing a window includes forming a first initial groove pattern recessed from an upper surface and a second initial groove pattern recessed from a lower surface on a mother substrate, forming first groove patterns overlapping the first initial groove pattern and recessed from the upper surface, and second groove patterns overlapping the second initial groove pattern, recessed from the lower surface, and alternately arranged with the first groove patterns to form a substrate from the mother substrate, forming first filling layers in the first groove patterns, forming a second filling layer covering the first filling layers, forming third filling layers in the second groove patterns, and forming a fourth filling layer covering the third filling layers.

In an embodiment, in the forming of the first and second initial groove patterns, a first outer recessed space and a second outer recessed space may each be provided by the first initial groove pattern and the second initial groove pattern, in the forming of the first and second groove patterns, first inner recessed spaces and second inner recessed spaces may each be provided by the first groove patterns and the second groove patterns, the first filling layers may each be filled in the first inner recessed spaces, and the second filling layer may be filled in the first outer recessed space, and the third filling layers may each be filled in the second inner recessed spaces, and the fourth filling layer may be filled in the second outer recessed space.

In an embodiment, the forming of the first filling layers may include filling a first filling resin through an inkjet method, and in the filling of the first filling resin, the first filling resin may be provided at every position corresponding to the first groove patterns, and provided in the range of about 70% to about 80% of a maximum width of the corresponding first groove pattern among the first groove patterns.

In an embodiment, the forming of the first filling layers may include filling the first filling resin through an inkjet method and curing the filled first filling resin, and the curing of the filled first filling resin may be performed after waiting for a predetermined period of time after the filling of the first filling resin.

In an embodiment, the forming of the second filling layer may include filling a second filling resin through an inkjet method, and the second filling resin may continuously be provided from one end of the first outer recessed space provided by the first initial groove pattern to the other end of the first outer recessed space.

In an embodiment, the first and second initial groove patterns may each have a depth of about 14 μm to about 20 μm.

In accordance with one or more embodiments, a window for a display device comprising: a non-pattern portion in a non-folding region of the display device; a pattern portion in a folding region of the display device and including: a substrate having first grooves and second grooves arranged in an alternating pattern, the first grooves oriented in a first direction and the second grooves oriented in the first direction, wherein a thickness of the substrate in the pattern portion is less than a thickness of the substrate in the non-pattern portion.

An upper surface of the substrate in the pattern portion may be recessed relative to an upper surface of the non-pattern portion. A lower surface of the substrate in the pattern portion may be recessed relative to a lower surface of the non-pattern portion.

The pattern portion may comprise first filling layers disposed in the first grooves; a second filling layer disposed over the first filling layers; third filling layers disposed in the second grooves; and a fourth filling layer covering the third filing layers. Upper surfaces of the first filling layers may be at a lower height than an upper surface of the non-pattern portion. An upper surface of the second filling layer and an upper surface of the non-pattern portion may be substantially coplanar. A lower surface of the fourth filling layer and a lower surface of the non-pattern portion may be substantially coplanar. The first through fourth filling layers may have a same refractive index as the substrate.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view showing an unfolding state of a display device according to an embodiment of the inventive concept;

FIGS. 2A to 2D are perspective views showing a folding state of a display device according to an embodiment of the inventive concept;

FIG. 3 is an exploded perspective view of a display device according to an embodiment of the inventive concept;

FIG. 4 is a cross-sectional view of a display device taken along line I-I′ shown in FIG. 3 according to an embodiment;

FIG. 5 is a perspective view of some components of a window according to an embodiment of the inventive concept, and FIG. 5B is a cross-sectional view enlarging some components of a window according to an embodiment of the inventive concept;

FIG. 6A is a perspective view of some components of a window according to an embodiment of the inventive concept, and FIG. 6B is a cross-sectional view enlarging some components of a window according to an embodiment of the inventive concept;

FIG. 7 is a cross-sectional view enlarging some components of a window according to an embodiment of the inventive concept;

FIGS. 8A to 8H show operations included in a process of manufacturing a window according to an embodiment of the inventive concept;

FIGS. 9A to 9L show operations included in a process of manufacturing a window according to an embodiment of the inventive concept; and

FIGS. 10A to 10L show operations included in a process of manufacturing a window according to an embodiment of the inventive concept.

### DETAILED DESCRIPTION

It will be understood that when an element (or a region, a layer, a portion, or the like) is referred to as “being on”, “connected to” or “coupled to” another element, it may be directly disposed on, connected or coupled to the other element, or intervening elements may be disposed therebetween.

Like reference numerals refer to like elements. In addition, in the drawings, the thickness, the ratio, and the dimensions of elements are exaggerated for an effective description of technical contents. The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense. In addition, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the inventive concept will be described with reference to the accompanying drawings.

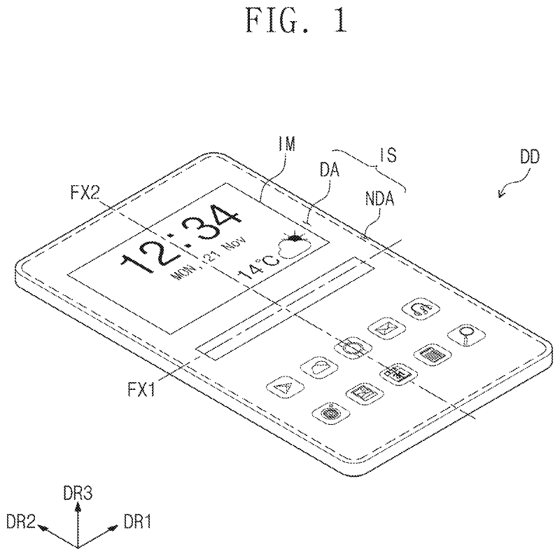

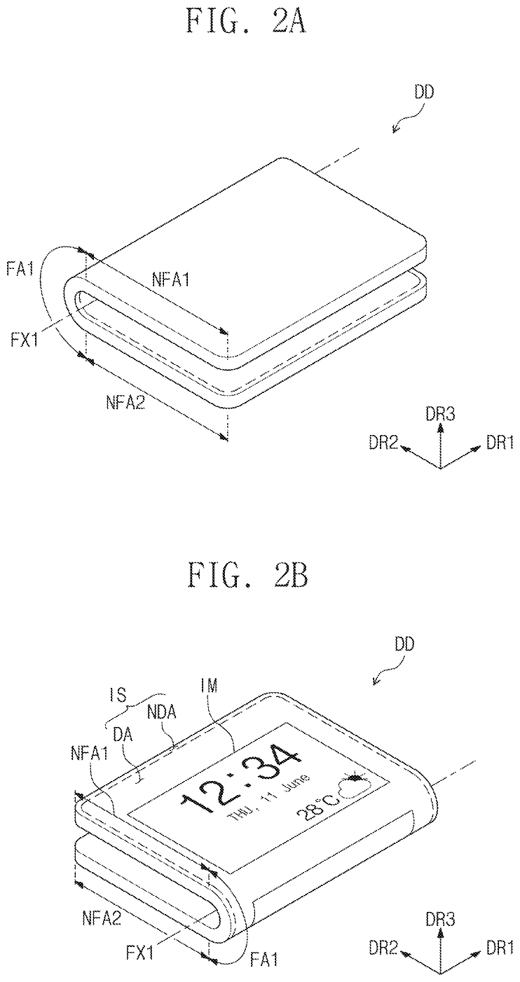

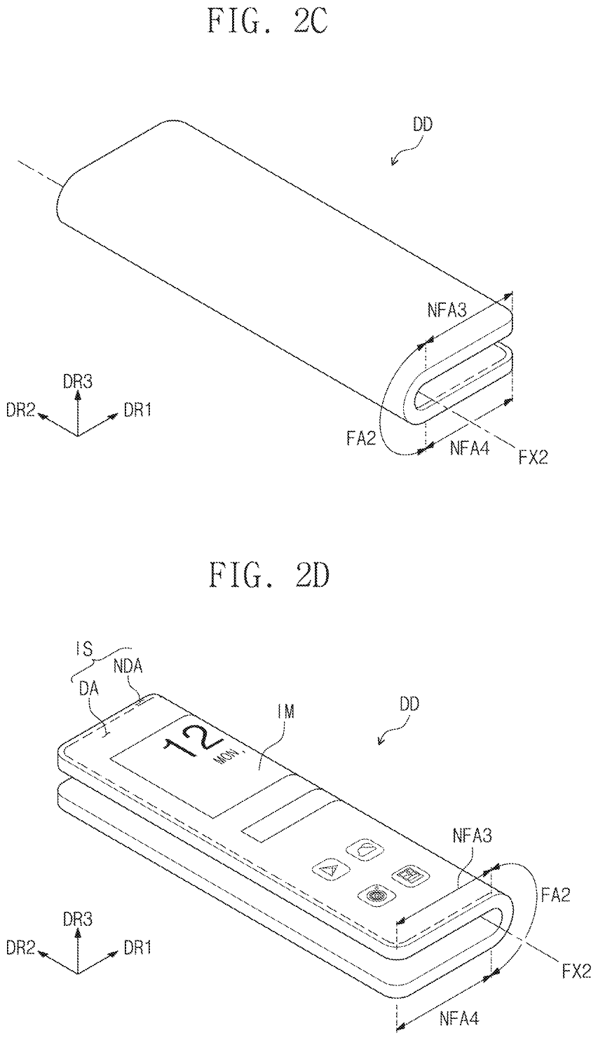

FIG. 1 is a perspective view showing an unfolded state of a display device DD according to an embodiment. FIGS. 2A to 2D are perspective views showing various folding states of a display device DD shown in FIG. 1.

The display device DD may be activated according to electrical signals and in operation displays various types of images IM. The display device DD may be used in multiple electronic devices for displaying images IM. For example, the display device DD may not only be used for large-sized electronic devices (such as television sets, monitors or the like), but may also be used for small-and medium-sized electronic devices such as mobile phones, tablets, car navigation units, game consoles, or the like. However, the display device DD is not limited to the examples described above and may be used in various other types of electronic devices according to the inventive concept.

Referring to FIG. 1, a front surface of the display device DD may be defined as a display surface IS. In an unfolded state, the display surface IS of the display device DD may correspond to a plane defined by a first direction DR1 and a second direction DR2 crossing the first direction DR1. The display surface IS may display the image IM toward a third (or thickness) direction DR3 perpendicular to the plane defined by the first and second directions DR1 and DR2.

Drawings described herein show the first to third directions DR1 to DR3. The first to third directions DR1, DR2, and DR3 described herein are relative concepts, and may thus be changed to one or more other directions. In each of the drawings, directions indicated by the first to third directions DR1, DR2, and DR3 are shown using the same reference numerals.

As used herein, a front surface (or an upper surface) and a rear surface (or a lower surface) of respective members may be defined with respect to a direction in which the image IM is displayed. The upper and lower surfaces may oppose each other in the third direction DR3, and a normal direction of each of the upper and lower surfaces may be parallel to the third direction DR3. The distance between the upper surface and the lower surface along the third direction DR3 may correspond to a thickness of a member. Herein, the phrase “when viewed on a plane” may include a view of a structure in the third direction DR3 or a direction opposite to the third direction DR3.

The display surface IS of the display device DD may include a display region DA and a non-display region NDA. The display region DA may be a portion in which images

IM are displayed. The non-display region NDA may be a portion in which images IM are not displayed. Users may view an image IM displayed through the display region DA. The image IM may be dynamic images or still images. FIG. 1 shows a plurality of application icons and clock widgets as an example of the image IM.

The display region DA may have a predetermined shape, e.g., a tetragonal shape. However, this is presented as an example, and the display region DA may have a different shape in another embodiment. The non-display region NDA may completely or partially surround the display region DA. However, the embodiment of the inventive concept is not limited thereto. For example, the non-display region NDA may be placed adjacent to only one side of the display region DA, or may be omitted.

As shown in FIG. 1, when viewed on a plane, the display device DD has a long side extending in the first direction DR1, a short side extending in the second direction DR2, and a rectangular shape having rounded corners. However, the shape of the display device DD is not limited thereto, and the display devices DD may have a different shape in another embodiment.

The display device DD is presented as an example where a cross-sectional display surface IS is defined. In one embodiment, the display device DD may have a double-sided display surface in which the display surface IS is defined in both the cross-sectional area and the rear surface. However, the display surface of the display device DD may be arranged in other ways.

The display device DD may be a foldable display device. The display device DD may be folded with respect to at least one virtual folding axis extending in a predetermined direction. FIG. 1 shows, as an example, a first folding axis FX1 extending in the first direction DR1 and a second folding axis FX2 extending in the second direction DR2. The first folding axis FX1 may be parallel to the short-side direction of the display device DD. The second folding axis FX2 may be parallel to the long-side direction of the display device DD. The display device DD of an embodiment may be folded with respect to at least one of the first folding axis FX1 or the second folding axis FX2.

FIGS. 2A and 2B are perspective views of the display device DD according to an embodiment, which is folded with respect to the first folding axis FX1. FIGS. 2C and 2D are perspective views of the display device DD according to an embodiment, which is folded with respect to the second folding axis FX2.

The display device DD may be divided into a folding region and a non-folding region according to operation modes. The folding region may be a portion curved to have a predetermined curvature when the display device DD is folded with respect to a folding axis. The non-folding region may be a flat portion when the display device DD is folded with respect to a folding axis.

The display device DD may include at least one folding region and one non-folding region. FIGS. 2A to 2D show embodiments of the display device DD including one folding region and two non-folding regions adjacent to the folding region with respect to one folding axis. However, the embodiment of the inventive concept is not limited thereto. For example, the display device DD may include a plurality of folding regions, each folded with respect to a plurality of folding axes. The number of folding and non-folding regions included in the display device DD may be one, two, or more than two.

Referring to FIGS. 1, 2A, and 2B, when folded with respect to the first folding axis FX1, the display device DD may include a first folding region FA1, a first non-folding region NFA1, and a second non-folding region NFA2. The first folding region FA1 may be a portion that surrounds the first folding axis FX1 and is folded with a predetermined curvature. The first non-folding region NFA1 may be adjacent to one side of the first folding region FA1 extending along the second direction DR2 in the non-folded state. The second non-folding region NFA2 may be placed adjacent to the other side of the first folding region FA1 extending along a direction opposite to the second direction DR2 in the non-folded state.

Referring to FIGS. 1, 2C, and 2D, when folded with respect to the second folding axis FX2, the display device DD may include a second folding region FA2, a third non-folding region NFA3, and a fourth non-folding region NFA4. The second folding region FA2 may surround the second folding axis FX2 and is folded with a predetermined curvature. The third non-folding region NFA3 may be adjacent to one side of the second folding region FA2 extending along a direction opposite to the first direction DR1 in the non-folding state. The fourth non-folding region NFA4 may be adjacent to the other side of the second folding region FA2 along the first direction DR1 in the non-folded state.

Referring to FIGS. 2A to 2D, the display device DD may be in-folded or out-folded. In-folding may include the case where the display surface IS overlaps a folding region of the display device DD and is folded to face a folding axis. When in-folded, all or a portion of the display surface IS is not visible. Out-folding may include the case where the rear surface overlaps a folding region of the display device DD and is folded to face a folding axis. When out-folded, the display surface IS is visible. The display device DD may be manufactured to enable both in-folding and out-folding, or may be manufactured to enable any one of in-folding or out-folding.

FIG. 2A shows examples of the display device DD in-folded with respect to a first folding axis FX1, and FIG. 2C shows a display device DD in-folded with respect to a second folding axis FX2. More specifically, as shown in FIG. 2A, portions of the display surface IS overlapping the first non-folding region NFA1 and the second non-folding region NFA2 of the in-folded display device DD may face each other. As shown in FIG. 2C, portions of the display surface IS overlapping the third non-folding region NFA3 and the fourth non-folding region NFA4 of the in-folded display device DD may face each other. In these cases, the rear surface of the in-folded display device DD (e.g., the surface which does not include the display surface IS) may be exposed to the outside. Accordingly, users may not view all or a portion of the image IM provided by the display device DD in the unfolded state.

FIG. 2B shows examples of the display device DD out-folded with respect to the first folding axis FX1, and FIG. 2C shows a display device DD out-folded with respect to the second folding axis FX2. As shown in FIG. 2B, portions of the display surface IS overlapping the first non-folding region NFA1 and the second non-folding region NFA2 of the out-folded display device DD may be exposed to the outside toward directions opposite to each other. As shown in FIG. 2B, portions of the display surface IS overlapping the third non-folding region NFA3 and the fourth non-folding region NFA4 of the out-folded display device DD may be exposed to the outside toward directions opposite to each other. Accordingly, users may view at least a portion of the image IM provided from the display device DD in a folded state.

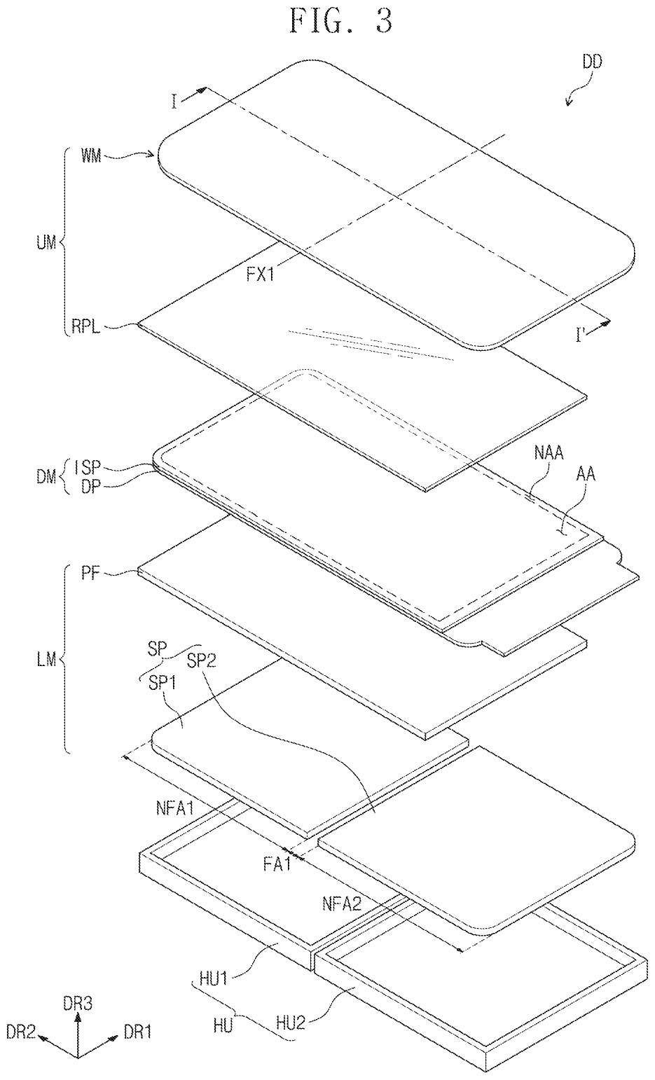

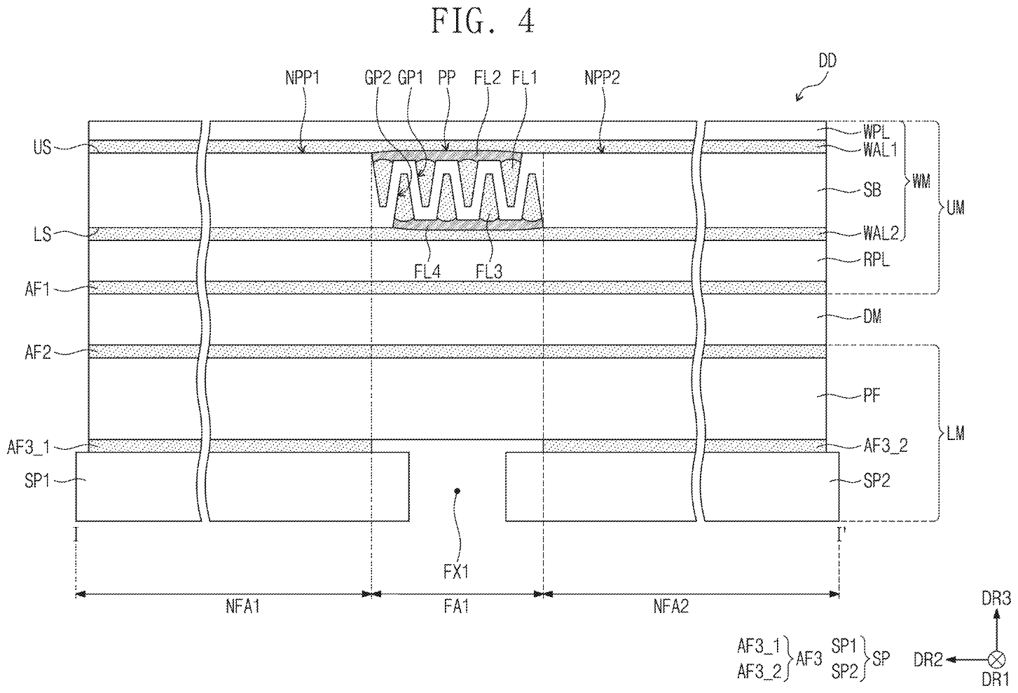

FIG. 3 is an exploded perspective view of the display device DD according to an embodiment. FIG. 4 is a cross-sectional view of the display device DD taken along section line I-I′ shown in FIG. 3.

Referring to FIGS. 3 and 4, the display device DD according to an embodiment of the inventive concept may include a display module DM displaying images, an upper module UM disposed on the display module DM, a lower module LM disposed below the display module DM, and a housing HU. The display device DD may further include a mechanical structure (or a hinge structure) configured to control an operation (or bending operation) of the display device DD.

The display module DM constitutes a portion of the display device DD and may generate images. The display module DM may include a display panel DP and an input sensing unit ISP. The display panel DP according to an embodiment of the inventive concept may be a light emitting display panel, but may be another type of display panel in another embodiment. For example, the display panel DP may be an organic light emitting display panel, an inorganic light emitting display panel, or a quantum dot light emitting display panel. An emission layer of the organic light emitting display panel may include an organic light emitting material, and an emission layer of the inorganic light emitting display panel may include an inorganic light emitting material. An emission layer of the quantum dot light emitting display panel may include quantum dots, quantum rods, and the like. Hereinafter, the display panel DP will be described as an organic light emitting display panel.

The display panel DP may be a flexible display panel. Accordingly, the display panel DP may be entirely rollable, or folded or unfolded with respect to the folding axis FX1.

The input sensing unit ISP may be directly disposed on the display panel DP. According to an embodiment of the inventive concept, the input sensing unit ISP may be formed on the display panel DP through a roll-to-roll process. For example, when the input sensing unit ISP is directly disposed on the display panel DP, an adhesive film is not disposed between the input sensing unit ISP and the display panel DP. However, the embodiment of the inventive concept is not limited thereto. In one embodiment, an adhesive film may be disposed between the input sensing unit ISP and the display panel DP. In this case, the input sensing unit ISP is not manufactured along with the display panel DP through a roll-to-roll process, and after being manufactured through a separate process from the display panel DP, the input sensing unit ISP may be fixed on an upper surface of the display panel DP through an adhesive film.

The display panel DP generates images, and the input sensing unit ISP acquires coordinate information of external inputs (e.g., a touch event) from users.

The upper module UM may include a window WM disposed on the display module DM. The window WM may include an optically transparent insulating material. Accordingly, images generated in the display module DM may be readily recognized by users through the window WM.

The window WM may include a substrate SB, filling layers FL1 and FL2, cover layers CL1 and CL2, and a window protection layer WPL. The substrate SB may include an optically transparent material. For example, the substrate SB may include a glass substrate, and specifically may include a chemically strengthened glass substrate. When the substrate SB includes a glass substrate, the substrate may have excellent esthetics and an ability to prevent nicks or scratches caused by sharp objects.

The substrate SB may include a pattern portion PP and non-pattern portions NPP1 and NPP2. The pattern portion PP may correspond to the folding region FA1. The non-pattern portions NPP1 and NPP2 may correspond to the non-folding regions NFA1 and NFA2, respectively. The non-pattern portions NPP1 and NPP2 may include a first non-pattern portion NPP1 corresponding to the first non-folding region NFA1 and a second non-pattern portion NPP2 corresponding to the second non-folding region NFA2. The pattern portion PP may be disposed between the first and second non-pattern portions NPP1 and NPP2.

The substrate SB may include an upper surface US and a lower surface LS. The upper surface US and the lower surface LS may be two surfaces facing each other adjacent to respective sides of the substrate SB, and may be, for example, two surfaces facing each other in the third direction DR3.

The pattern portion PP may include a plurality of first groove patterns GP1 and a plurality of second groove patterns GP2. The first groove patterns GP1 have a shape recessed from the upper surface US of the substrate SB. The second groove patterns GP2 have a shape recessed from the lower surface LS of the substrate SB.

As an example of an embodiment of the inventive concept, when the folding axis FX1 extends in the first direction DR1, the first groove patterns GP1 may be arranged to be spaced apart from each other in the second direction DR2, and the second groove patterns GP2 may be arranged to be spaced apart from each other in the second direction DR2. The first groove patterns GP1 and the second groove patterns GP2 may be alternately arranged in the second direction DR2. In one embodiment, when the folding axis FX2 (e.g., see FIGS. 2C and 2D) extends in the second direction DR2, the first groove patterns GP1 may be arranged to be spaced apart from each other in the first direction DR1, and the second groove patterns GP2 may be arranged to be spaced apart from each other in the first direction DR1.

In the present embodiment, the filling layers FL1, FL2, FL3, and FL4 may include first filling layers FL1, a second filling layer FL2, third filling layers FL3, and a fourth filling layer FL4.

The first groove patterns GP1 may each be filled by the first filling layers FL1. For example, recessed spaces formed by the first groove patterns GP1 may be filled by the first filling layers FL1. The second filling layer FL2 may be disposed on the first filling layers FL1 and may cover the upper surface US of the substrate SB overlapping the first filling layers FL1 and the folding region FA1.

The second groove patterns GP2 may each be filled by the third filling layers FL3. For example, recessed spaces formed by the second groove patterns GP2 may be filled by the third filling layers FL3. The fourth filling layer FL4 may be disposed on the third filling layers FL3 and may cover the lower surface LS of the substrate SB overlapping the third filling layers FL3 and the folding region FA1. The first to fourth filling layers FL1, FL2, FL3, and FL4 may be provided only on the pattern portion PP and may not be provided on the first and second non-pattern portions NPP1 and NPP2.

The first to fourth filling layers FL1, FL2, FL3, and FL4 may each include a synthetic resin material. In one embodiment, the first to fourth filling layers FL1, FL2, FL3, and FL4 may each include a material having substantially the same refractive index as that of the substrate SB. As an example of an embodiment of the inventive concept, the first to fourth filling layers FL1, FL2, FL3, and FL4 may each include at least one of a urethane-based resin, an epoxy-based resin, a polyester-based resin, a polyether-based resin, an acrylate-based resin, an acrylonitrile-butadiene-styrene resin (ABS), or rubber. In one embodiment, the first to fourth filling layers FL1, FL2, FL3, and FL4 may each include at least one of phenylene, polyethylene terephthalate (PET), polyimide (PI), polyamide (PAI), polyethylene naphthalate (PEN), or polycarbonate (PC).

The window protection layer WPL may be disposed on the substrate SB, for example, on the second filling layer FL2. The window protection layer WPL may serve to protect the substrate SB from external shock.

The window protection layer WPL may include a synthetic resin material. As an example of an embodiment of the inventive concept, the window protection layer WPL may include at least one of a urethane-based resin, an epoxy-based resin, a polyester-based resin, a polyether-based resin, an acrylate-based resin, an acrylonitrile-butadiene-styrene resin (ABS), or rubber. In one embodiment, the window protection layer WPL may include at least one of phenylene, polyethylene terephthalate (PET), polyimide (PI), polyamide (PAI), polyethylene naphthalate (PEN), or polycarbonate (PC).

The window WM may further include a first window adhesive layer WAL1 and a second window adhesive layer WAL2. The first window adhesive layer WAL1 is disposed on the upper surface US of the substrate SB, and the second window adhesive layer WAL2 is disposed below the lower surface LS of the substrate SB. The first window adhesive layer WAL1 may be disposed between the substrate SB and the window protection layer WPL to attach the window protection layer WPL to the substrate SB. The second window adhesive layer WAL2 may bond the window WM with a member disposed below the window WM. The first and second window adhesive layers WAL1 and WAL2 may include an optically transparent adhesive material. As an example of an embodiment of the inventive concept, the first and second window adhesive layers WAL1 and WAL2 may each include a pressure sensitive adhesive (PSA), an optically clear adhesive (OCA), or an optically clear resin (OCR).

The window WM may be folded or unfolded with respect to the folding one or more folding axes, e.g., with respect to axis FX1. For example, when the display module DM is modified in shape, the shape of the window WM may be modified as well. The window WM transmits images from the display module DM while reducing external shock, to prevent the display module DM from being damaged or malfunctioning due to the external shock. The external shock may include a force that causes defects in the display module DM. For example, the external shock may be caused by an external force such as pressure or stress.

In addition, the upper module UM may further include at least one functional layer disposed between the display module DM and the window WM. As an example of an embodiment of the inventive concept, the functional layer may be an anti-reflection layer RPL that blocks external light reflection. The anti-reflection layer RPL may be bonded to the window WM through the second window adhesive layer WAL2.

The anti-reflection layer RPL may prevent an issue in which elements constituting the display module DM are viewed from the outside due to external light incident through a front surface of the display device DD. In one embodiment, the anti-reflection layer

RPL may include a retarder and a polarizer. The retarder may be a film type or a liquid crystal-coating-type and, for example, may include a λ/2 retarder and/or a λ/4 retarder. The polarizer may also be a film type or a liquid crystal-coating-type. The film type may include an elongated synthetic resin film, and the liquid crystal coating type may include liquid crystals arranged in a predetermined arrangement. The retarder and the polarizer may be implemented as one polarizing film. The functional layer may further include a protection film disposed above or below the anti-reflection layer RPL.

The upper module UM may further include a first adhesive film AF1 provided between the anti-reflection layer RPL and the display module DM. The first adhesive film AF1 may include an optically transparent adhesive material. As an example of an embodiment of the inventive concept, the first adhesive film AF1 may include a pressure sensitive adhesive (PSA), an optically clear adhesive (OCA), or an optically clear resin (OCR).

The display module DM may display images according to electrical signals and transmit/receive information on external inputs. The display module DM may be defined as an active region AA and a peripheral region NAA. The active region AA may be defined as a region for outputting images provided from the display module DM.

The peripheral region NAA is adjacent to the active region AA. For example, the peripheral region NAA may surround the active region AA. However, this is presented as an example, and the peripheral region NAA may be defined in various shapes, and is not limited to any one embodiment. According to an embodiment, the active region AA of the display module DM may correspond to at least a portion of the display region DA (e.g., see FIG. 1).

The lower module LM includes a support member SP disposed on a rear surface of the display module DM to support the display module DM. The support member SP may include a number of support plates which corresponds to the number of the non-folding regions NFA1 and NFA2. As an example of an embodiment of the inventive concept, the support member SP may include a first support plate SP1 corresponding to the first non-folding region NFA1, and a second support plate SP2 corresponding to the second non-folding region NFA2 and spaced apart from the first support plate SP1. Each of the first and second support plates SP1 and SP2 may for example, include a metal material or a plastic material.

When the display module DM is in a flat state, the first and second support plates SP1 and SP2 are spaced apart from each other in the second direction DR2. When the display module DM has a folded state with respect to the folding axis FX1, the first and second support plates SP1 and SP2 may be disposed to face (or overlap) each other in the thickness direction.

The first and second support plates SP1 and SP2 may be spaced apart at a location corresponding to the folding region FA1. The first and second support plates SP1 and SP2 may partially overlap the folding region FA1. For example, the distance between the first support plate and SP1 and the second support plate SP2 on the second direction DR2 may be less than the width of the folding region FA1.

The support member SP may further include a connection module configured to connect the first and second support plates SP1 and SP2. The connection module may include a hinge module or a multi-joint module.

According to another embodiment of the inventive concept, the support member SP may be provided as a singly body without being separated into the first and second support plates SP1 and SP2. In this case, the support member SP may be provided with a bending portion corresponding to the folding region FA1. In this case, an opening formed through the support member SP, or a groove recessed from one surface of the support member SP, may be provided in the bending portion.

The lower module LM may further include a protection film PF disposed between the display module DM and the support member SP. The protection film PF may be a layer disposed below the display module DM to protect a rear surface of the display module DM. The protection film PF may include a synthetic resin film, and, for example, may be a polyimide film or a polyethylene terephthalate film. However, this is merely an example, and the protection film PF may be made from different materials in another embodiment.

The lower module LM may further include a second adhesive film AF2 and a third adhesive film AF3. The second adhesive film AF2 may be disposed between the protection film PF and the display module DM. The third adhesive film AF3 may be disposed between the protection film PF and the support member SP. The protection film PF may be attached to the rear surface of the display module DM through the second adhesive film AF2. As an example of an embodiment of the inventive concept, the third adhesive film AF3 may include a first sub adhesive film AF3_1 and a second sub adhesive film AF3_2. The first sub-adhesive film AF3_1 may attach the first support member SP1 and the protection film PF, and the second sub-adhesive film AF3_2 may attach the second support member SP2 and the protection film PF. The first and second sub-adhesive films AF3_1 and AF3_2 may be spaced apart from each other with the folding region FA1 at least partially therebetween.

The second and third adhesive films AF2 and AF3 may include an optically transparent adhesive material. As an example of an embodiment of the inventive concept, the second and third adhesive films AF2 and AF3 may each include a pressure sensitive adhesive (PSA), an optically clear adhesive (OCA), or an optically clear resin (OCR).

The housing HU is bonded to the window WM to accommodate the other modules, e.g., the display module DM and the lower module LM. The housing HU is shown to include first and second housings HU1 and HU2 which are separated from each other, but is not limited thereto. The display device DD may further include a hinge structure configured to connect the first and second housings HU1 and HU2.

The substrate SB and the filling layers FL1, FL2, FL3, and FL4 according to an embodiment of the inventive concept will be described in detail with reference to the following drawings.

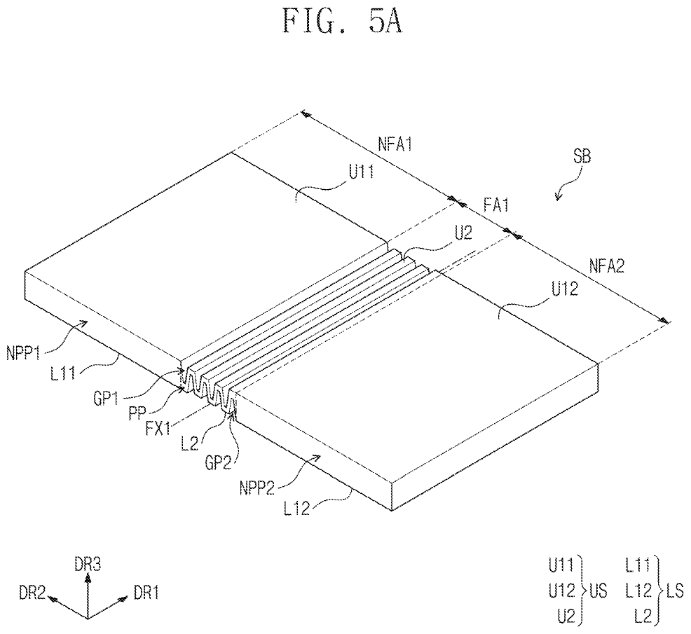

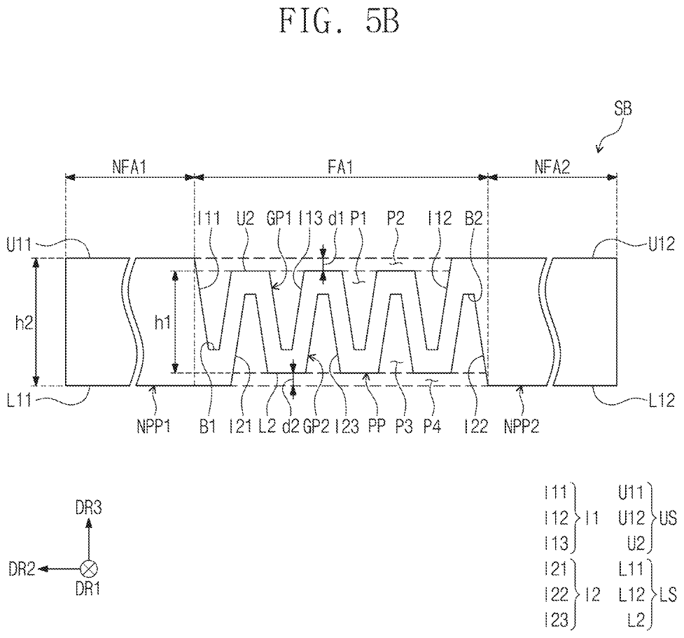

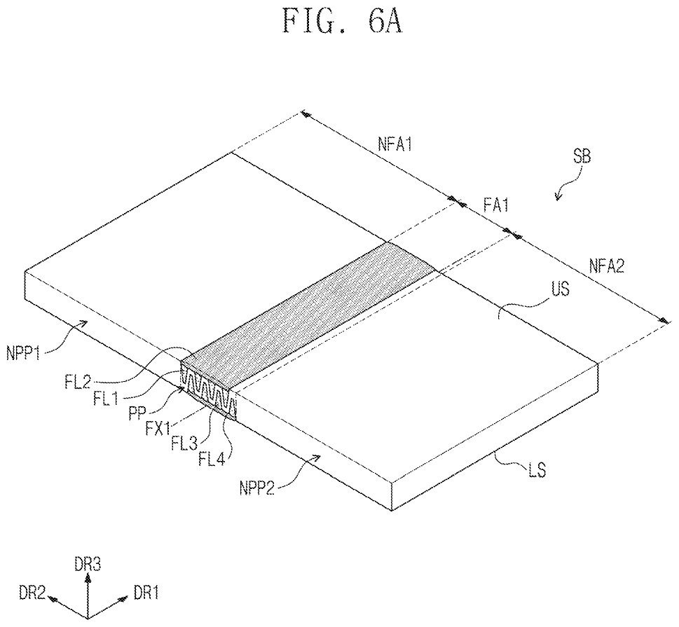

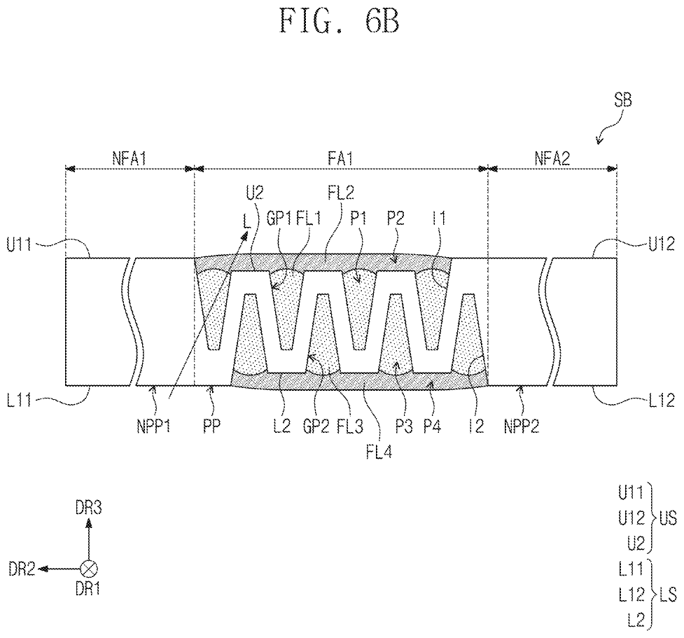

FIG. 5 is a perspective view of some components of the window WM according to an embodiment of the inventive concept. FIG. 5B is a cross-sectional view enlarging some components of the window WM according to an embodiment of the inventive concept. FIG. 6A is a perspective view of some components of the window WM according to an embodiment of the inventive concept, and FIG. 6B is a cross-sectional view enlarging some components of the window WM according to an embodiment of the inventive concept. FIGS. 5A and 5B show the substrate SB of the window WM (e.g., see FIG. 4), and FIGS. 6A and 6B show the substrate SB and the filling layers FL1, FL2, FL3, and FL4 of the window WM (e.g., see FIG. 4).

Referring to FIGS. 5A and 5B, the substrate SB may include a first non-pattern portion NPP1 corresponding to the first non-folding region NFA1, a second non-pattern portion NPP2 corresponding to the second non-folding region NFA2, and a pattern portion PP corresponding to the folding region FA. The substrate SB may include an upper surface US and a lower surface LS that face each other. The upper surface US may include first upper surfaces U11 and U12 in the non-pattern portions NPP1 and NPP2 and the second upper surface U2 in the pattern portion PP. The lower surface LS may include first lower surfaces L11 and L12 in the non-pattern portions NPP1 and NPP2 and a second lower surface L2 in the pattern portion PP.

In the present embodiment, the upper surface US of the substrate SB may include a (1-1)-th upper surface U11 overlapping the first non-folding region NFA1, a (1-2)-th upper surface U12 overlapping the second non-folding region NFA2, and second upper surfaces U2 overlapping the folding region FA. The (1-1)-th upper surface U11 may correspond to the upper surface US in the first non-pattern portion NPP1. The (1-2)-th upper surface U12 may correspond to the upper surface US in the second non-pattern portion NPP2 and a portion of the pattern portion PP adjacent thereto. The second upper surfaces U2 may correspond to the upper surfaces US in the other portion of the pattern portion PP. The second upper surfaces U2 may be disposed between the (1-1)-th and (1-2)-th upper surfaces U11 and U12 when viewed on a plane.

In the present embodiment, the second upper surfaces U2 may be disposed further inward of the substrate (e.g., at a different level) than the (1-1)-th and (1-2)-th upper surfaces U11 and U12. For example, the second upper surfaces U2 may be disposed to be more recessed than (1-1)-th and (1-2)-th upper surfaces U11 and U12. Accordingly, a step may be formed between the (1-1)-th and (1-2)-th upper surfaces U11 and U12 and the second upper surfaces U2.

The first groove patterns GP1 may have a groove shape recessed from the upper surface US of the substrate SB. The first groove patterns GP1 may each provide first recessed spaces P1. The first groove patterns GP1 may each have a stripe shape extending in a direction parallel to the folding axis FX1 (e.g., the first direction DR1). The first groove patterns GP1 may be arranged to be spaced apart from each other in the second direction DR2.

Among the first groove patterns GP1, the first groove pattern closest to the first non-pattern portion NPP1 may be formed by being recessed from the (1-1)-th upper surface U11 and the second upper surface U2. Among the first groove patterns GP1, the first groove pattern closest to the second non-pattern portion NPP2 may be formed by being recessed from the (1-2)-th upper surface U12 and the second upper surface U2. The remaining first groove patterns GP1 may be formed by being recessed from the second upper surfaces U2.

The first groove patterns GP1 may have a predetermined shape (e.g., trapezoidal shape) in a cross section, but may have a different shape in another embodiment. When the first groove patterns GP1 have a trapezoidal shape, the substrate SB may include first inner surfaces I1 and first bottom surfaces B1 constituting each of the first groove patterns GP1. The width of an upper end of the first groove patterns GP1 (e.g., the portion relatively adjacent to the upper surface US of the substrate SB) in the second direction DR2 may be greater than the width of a lower end (e.g., the portion relatively adjacent to the lower surface of the substrate SB) in the second direction DR2. Thus, the first groove patterns GP1 may have a tapered shape. For example, the first inner surfaces I1 facing each other may be positioned closer to one another toward the lower end that at the upper end of the first groove patterns GP1.

In an embodiment, the first bottom surfaces B1 may each be provided in a planar shape and may be arranged in a line in the second direction DR2. However, the embodiment of the inventive concept is not limited thereto, and the first bottom surfaces B1 may each have a different shape, e.g., a round shape.

The first inner surfaces I1 may include an (1-1)-th inner surface I11 extending from the (1-1)-th upper surface U11 to the adjacent first bottom surface B1, an (1-2)-th inner surface I12 extending from the (1-2)-th upper surface U2 to the adjacent first bottom surface B1, and an (1-3)-th inner surface I13 extending from the second upper surface U2 to the adjacent first bottom surface B1. In this case, the (1-3)-th inner surfaces I13 may be disposed between the (1-1)-th and (1-2)-th inner surfaces I11 and I12.

In cross-section, the length of each of the (1-1)-th and (1-2)-th inner surfaces I11 and I12 may be greater than the length of the (1-3)-th inner surfaces I13. Accordingly, portions of each of the (1-1)-th and (1-2)-th inner surfaces I11 and I12 may protrude upward further than the (1-3)-th inner surfaces I13. For example, each of the (1-1)-th and (1-2)-th inner surfaces I11 and I12 may include a portion protruding further than the second upper surfaces U2, and the protruding portions of the (1-1)-th and (1-2)-th inner surfaces I11 and I12 may face each other.

In the present embodiment, it is shown that the second upper surfaces U2 are disposed to be more recessed than the (1-1)-th and (1-2)-th upper surfaces U11 and U12. Accordingly, the (1-1)-th and (1-2)-th inner surfaces I11 and I12 may each include a portion that protrudes further than the second upper surfaces U2. A virtual plane defined by the extension of the (1-1)-th and (1-2)-th inner surfaces I11 and I12, and the second upper surfaces U2 may provide a second recessed space P2.

The second recessed space P2 may form a singly-body space with the first recessed spaces P1 provided by the first groove patterns GP1. The second recessed space P2 maybe disposed on (over) the first recessed spaces P1 and may continuously extend from the first recessed space P1 closest to the first non-pattern portion NPP1 to the first recessed space P1 closest to the second non-pattern portion NPP2.

In the present embodiment, the lower surface LS of the substrate SB may include a (1-1)-th lower surface L11 overlapping the first non-folding region NFA1, a (1-2)-th lower surface L12 overlapping the second non-folding region NFA2, and second lower surfaces L2 overlapping the folding region FA1. The (1-1)-th lower surface L11 may correspond to the lower surface LS in the first non-pattern portion NPP1 and a portion of the pattern portion PP adjacent thereto. The (1-2)-th lower surface L12 may correspond to the lower surface LS in the second non-pattern portion NPP2. The second lower surfaces L2 may correspond to the lower surfaces LS in the other portion of the pattern portion PP. The second lower surfaces L2 may be disposed between the (1-1)-th and (1-2)-th lower surfaces L11 and L12 when viewed on a plane.

In the present embodiment, the second lower surfaces L2 may be disposed further inward of the substrate than the (1-1)-th and (1-2)-th lower surfaces L11 and L12 in a thickness direction DR3. For example, the second lower surfaces L2 may be disposed to be more recessed than (1-1)-th and (1-2)-th lower surfaces L11 and L12. Accordingly, a step may be formed between the (1-1)-th and (1-2)-th lower surfaces L11 and L12 and the second lower surfaces L2.

The second groove patterns GP2 may have a groove shape recessed from the lower surface LS of the substrate SB. The second groove patterns GP2 may each provide third recessed spaces P3. The second groove patterns GP2 may each have a stripe shape extending in a direction parallel to the folding axis FX1 (e.g., the first direction DR1). The second groove patterns GP2 may be arranged to be spaced apart from each other in the second direction DR2. The second groove patterns GP2 and the first groove patterns GP1 may be alternately arranged in the second direction DR2.

Among the second groove patterns GP2, the second groove pattern closest to the first non-pattern portion NPP1 may be formed by being recessed from the (1-1)-th lower surface L11 and the second lower surface L2. Among the second groove patterns GP2, the second groove pattern closest to the second non-pattern portion NPP2 may be formed by being recessed from the (1-2)-th lower surface L12 and the second lower surface L2. The remaining second groove patterns GP2 may be formed by being recessed from the second lower surfaces L2.

The second groove patterns GP2 may have a predetermined shape, e.g., a trapezoidal shape, when taken in cross-section. When having a trapezoidal shape, the substrate SB may include second inner surfaces I2 and second bottom surfaces B2 constituting each of the second groove patterns GP2. The width of a lower end of the second groove patterns GP2 (e.g., the portion relatively adjacent to the lower surface US of the substrate SB) in the second direction DR2 may be greater than a width of an upper end (e.g., the portion relatively adjacent to the upper surface US of the substrate SB) in the second direction DR2. For example, the second inner surfaces I2 facing each other may be positioned closer toward the upper end from the lower end of the second groove patterns GP2.

In an embodiment, the second bottom surfaces B2 may each be provided in a planar shape and may be arranged in a line in the second direction DR2. However, the embodiment of the inventive concept is not limited thereto, and the second bottom surfaces B2 may each have another shape, e.g., a round shape.

In an embodiment, the first groove patterns GP1 and the second groove patterns GP2 may be linearly symmetric to each other. For example, the width at the upper end of the first groove patterns GP1 and the width at the lower end of the second groove patterns GP2 maybe substantially the same. Also, the width at the lower end of the first groove patterns GP1 and the width at the upper end of the second groove patterns GP2 may be substantially the same. In addition, the first groove patterns GP1 and the second groove patterns GP2 may have the same depth. However, the embodiment of the inventive concept is not limited thereto, and the first groove patterns GP1 and the second groove patterns GP2 may be different in shape and may not be linearly symmetric to each other. For example, the width of the first groove patterns GP1 and the width of the second groove patterns GP2 may be different, and/or the depth of the first groove patterns GP1 and the depth of the second groove patterns GP2 may be different.

The second inner surfaces I2 may include a (2-1)-th inner surface I21 extending from the (1-1)-th lower surface L11 to the adjacent second bottom surface B2, a (2-2)-th inner surface I22 extending from the (1-2)-th lower surface L12 to the adjacent second bottom surface B2, and a (2-3)-th inner surface I23 extending from the second lower surface L2 to the adjacent second bottom surface B2. The (2-3)-th inner surfaces I23 may be disposed between the (2-1)-th and (2-2)-th inner surfaces I21 and I22.

In cross-section, the length of each of the (2-1)-th and (2-2)-th inner surfaces I21 and I22 may be greater than the length of the (2-3)-th inner surfaces I23. Accordingly, portions of each of the (2-1)-th and (2-2)-th inner surfaces I21 and I22 may protrude downward further than the (2-3)-th inner surfaces I23. For example, each of the (2-1)-th and (2-2)-th inner surfaces I21 and I22 may include a portion protruding further than the second lower surfaces L2, and the protruding portions of the (2-1)-th and (2-2)-th inner surfaces I21 and I22 may face each other.

In the present embodiment, it is shown that the second lower surfaces L2 are disposed to be more recessed than the (1-1)-th and (1-2)-th lower surfaces L11 and L12. Accordingly, the (2-1)-th and (2-2)-th inner surfaces I21 and I22 may each include the portion protruding further than the second lower surfaces L2, and a plane defined by the extension of the (2-1)-th and (2-2)-th inner surfaces I21 and I22 and the second lower surfaces L2 may provide a fourth recessed space P4.

The fourth recessed space P4 may form a singly-body space with the third recessed spaces P3 provided by the second groove patterns GP2. The fourth recessed space P4 may be disposed on the third recessed spaces P3 and may continuously extend from the third recessed space P3 closest to the first non-pattern portion NPP1 to the third recessed space P3 closest to the second non-pattern portion NPP2.

According to an embodiment of the inventive concept, the second upper surfaces U2 are arranged to be more recessed than the (1-1)-th and (1-2)-th upper surfaces U11 and U12. Also, the second lower surfaces L2 are arranged to be more recessed than the (1-1)-th and (1-2)-th lower surfaces L11 and L12. As a result, the height h1 of the pattern portion PP of the substrate SB is less than the height h2 of the non-pattern portions NPP1 and NPP2. (Herein, the height h1 of the pattern portion PP may indicate a height in the thickness direction from an imaginary plane to which the second lower surfaces L2 extend to an imaginary plane to which the second upper surfaces U2 extend. The height h2 of the non-pattern portion NPP1 and NPP2 may indicate a height in the thickness direction from the (1-1)-th lower surface L11 to the (1-1)-th upper surface U11 or from the (1-2)-th lower surface L12 to the (1-2)-th upper surface U12.)

Referring to FIGS. 5A to 6B, the substrate SB may be partially or entirely filled by filling layers FL1, FL2, FL3, and FL4. The filling layers FL1, FL2, FL3, and FL4 may include first filling layers FL1, a second filling layer FL2, third filling layers FL3, and a fourth filling layer FL4. The first filling layers FL1 may each be disposed in the first recessed spaces P1 provided by the first groove patterns GP1, e.g., the first filling layers FL1 may each fill at least a portion of the corresponding first recessed space P1.

FIGS. 6A and 6B show that the first filling layers FL1 cover at least a portion of each of the first inner surfaces I1 and do not cover the second upper surfaces U2 as an example. In one embodiment (e.g., depending on process conditions), some of the first filling layers FL1 may be formed to partially cover the second upper surface U2.

The second filling layer FL2 may be disposed in the second recessed space P2. For example, the second filling layer FL2 may fill the second recessed space P2. The second filling layer FL2 may be disposed in an area corresponding to a step between the (1-1)-th and (1-2)-th upper surfaces U11 and U12 and the second upper surfaces U2. The second filling layer FL2 may cover the second upper surfaces U2, at least a portion of the (1-1)-th inner surface I11 protruding further than the (1-3)-th inner surface I13, and at least a portion of the (1-2)-th inner surface I12 protruding further than the (1-3)-th inner surface I13.

The third filling layers FL3 may each be disposed in the third recessed spaces P3 provided by the second groove patterns GP2. For example, each of the third filling layers FL3 may fill at least a portion of a corresponding one of the third recessed spaces P3.

FIGS. 6A and 6B show that the third filling layers FL3 cover at least a portion of each of the second inner surfaces I2 and do not cover the second lower surfaces L2 as an example. In one embodiment (e.g., depending on process conditions), some of the third filling layers FL3 may be formed to partially cover the second lower surface L2.

The fourth filling layer FL4 may be disposed in the fourth recessed space P4. For example, the fourth filling layer FL4 may partially or completely fill the fourth recessed space P4. The fourth filling layer FL4 may be disposed in a step between the (1-1)-th and (1-2)-th lower surfaces L11 and L12 and the second lower surfaces L2. The fourth filling layer FL4 may cover the second lower surfaces L2, at least a portion of the (2-1)-th inner surface I21 protruding further than the (2-3)-th inner surface I23, and at least a portion of the (2-2)-th inner surface I22 protruding further than the (2-3)-th inner surface I23.

The first to fourth filling layers FL1, FL2, FL3, and FL4 may include a material having substantially the same refractive index as that of the substrate SB. In the present embodiment, those having substantially the same refractive index may have a refractive index difference of a predetermined amount, e.g., about 0.003 or less. For example, the substrate SB may have a refractive index of about 1.490 to about 1.520, and the first to fourth filling layers FL1, FL2, FL3, and FL4 may have a refractive index different from that of the substrate SB by about 0.003 or less. However, the refractive index of the substrate SB is not limited thereto, and the refractive index may be set differently according to, for example, the thickness of the substrate SB.

Because the filling layers FL1, FL2, FL3 and FL4 have substantially the same refractive index as the substrate SB and cover the first and second groove patterns GP1 and GP2, interference fringes caused by the first and second groove patterns GP1 and GP2 may be prevented from being viewed by users. And, this is so, even when the substrate SB, which includes the first and second groove patterns GP1 and GP2, has folding properties.

In addition, the first to fourth filling layers FL1, FL2, FL3, and FL4 may include a material having substantially the same Abbe No. as that of the substrate SB. For example, the substrate SB and the first to fourth filling layers FL1, FL2, FL3, and FL4 may have an Abbe No. of about 50. However, the embodiment of the inventive concept is not limited thereto, and the Abbe No. of the substrate SB and the first to fourth filling layers FL1, FL2, FL3, and FL4 may be different according, for example, to the thickness of the substrate SB.

According to an embodiment of the inventive concept, the substrate SB provides the second recessed space P2 and the fourth recessed space P4, and may thus provide a space in which the second filling layer FL2 and the fourth filling layer FL4 are respectively filled. The first filling layers FL1 may be formed to have different heights from the first bottom surfaces B1 due to process errors, which will be described later. But, because the second filling layer FL2 covers the first filling layers FL1, a relatively flat surface may be provided to a structure attached above the upper surface US of the substrate SB. In addition, the third filling layers FL3 may be formed to have different heights from the second bottom surfaces B2 due to process errors, which will be described later. But, because the fourth filling layer FL4 covers the third filling layers FL3, a relatively flat surface may be provided to a structure attached below the lower surface LS of the substrate SB. Accordingly, the window WM (e.g., see FIG. 3) may have improved surface quality through prevention of the formation of a step which may otherwise be formed by the groove patterns GP1 and GP2 and the first and third filling layers FL1 and FL3 if the filling layers FL2 and FL4 were not included. The window may also have improved surface quality because such a step will not be viewed by a user. Accordingly, the display device DD (see FIG. 3) may have improved viewability.

In addition, according to an embodiment of the inventive concept, the second upper surfaces U2 are disposed to be more recessed (e.g., at a lower height level) than the (1-1)-th and (1-2)-th upper surfaces U11 and U12. Accordingly, of the light L provided from the display panel DP (e.g., see FIG. 3) and passing through the window WM (e.g., see FIG. 3), the amount of the light may be reduced that sequentially passes along a path that extends through the substrate SB, the filling layers FL1 and FL2, and the substrate SB again. For example, of the light L passing through the substrate SB and through the filling layers FL1 and FL2, the amount of light passing through the substrate SB again may be reduced. Accordingly, the light path may be less distorted.

In the present embodiment, the second and fourth recessed spaces P2 and P4 may each have depths (or thicknesses) d1 and d2 in a predetermined range, e.g., about 14 μm to about 20 μm. For example, the second upper surfaces U2 may be disposed to be recessed by about 14 μm to about 20 μm from a plane in which the (1-1)-th upper surface U11 or the (1-2)-th upper surface U12 extends. In addition, the second lower surfaces L2 may be disposed to be recessed about 14 μm to about 20 μm from a plane in which the (1-1)-th lower surface L11 or the (1-2)-th lower surface L12 extends. In this case, a space suitable for forming a planarized surface covering the step formed between the first filling layers FL1 and the second upper surfaces U2 and the step formed between the third filling layers FL3 and the second lower surfaces L2 may be provided in the second and fourth filling layers FL2 and FL4.

According to one embodiment, the second and fourth filling layers FL2 and FL4 may each be formed by applying a filling resin (e.g., through an inkjet process). When the filling resin spreads sufficiently (by receiving energy from a surface after landing), the filling resin may be formed to have a predetermined height. Thus, the depths d1 and d2 of the second and fourth recessed spaces P2 and P4 may be suitably set according to the viscosity of the filling resin forming the second and fourth filling layers FL2 and FL4 and/or inkjet process conditions (e.g., the size of a spray nozzle).

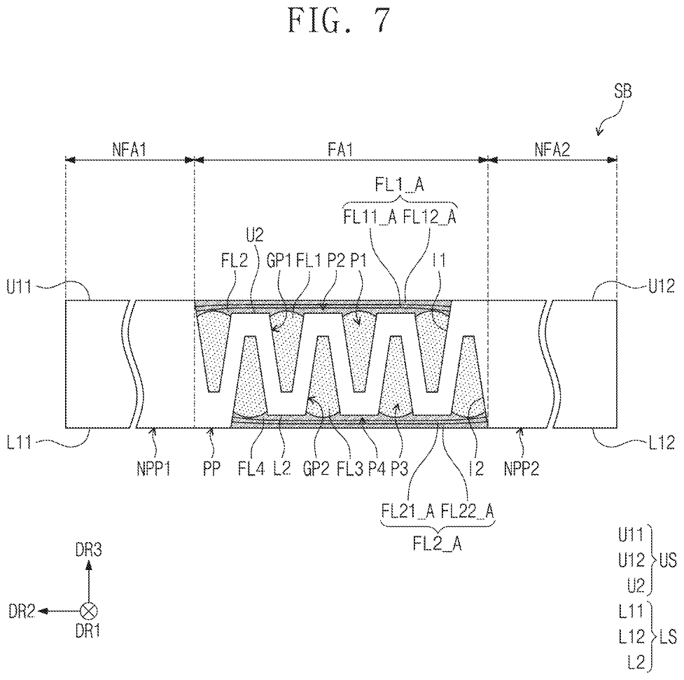

FIG. 7 is a cross-sectional view which is enlarged to show some components of a window according to an embodiment of the inventive concept. For example, FIG. 7 shows the substrate SB and the filling layers FL1, FL2, FL3, FL4, FL1_A, and FL2_A of the window WM (e.g., see FIG. 4).

Referring to FIG. 7, the filling layers FL1, FL2, FL3, FL4, FL1_A, and FL2_A according to the present embodiment may include first filling layers FL1, a second filling layer FL2, third filling layers FL3, a fourth filling layer FL4, and additional filling layers FL1_A and FL2_A. The filling layers according to the present embodiment may therefore include additional filling layers FL1_A and FL2_A compared to the embodiment shown in FIGS. 6A and 6B. While the additional filling layers are shown to include the two additional filling layers (e.g., first additional filling layer FL1_A and second additional filling layer FL2_A), the number of additional filling layers may be one or more than two in another embodiment.

In the present embodiment, the second filling layer FL2 and the first additional filling layer FL1_A may be disposed in the second recessed space P2. In other words, the second filling layer FL2 and the first additional filling layer FL1_A may be filled in the second recessed space P2. The second filling layer FL2 may be disposed on the first filling layers FL1 and may cover the first filling layers FL1 and the second upper surfaces U2. The first additional filling layer FL1_A may be disposed on the second filling layer FL2 and may cover the second filling layer FL2.

As an example of an embodiment of the inventive concept, the first additional filling layer FL1_A may include a (1-1)-th additional filling layer FL11_A and a (1-2)-th additional filling layer FL12_A, which are sequentially stacked in the third (thickness) direction DR3. The (1-1)-th additional filling layer FL11_A may cover the second filling layer FL2, and the (1-2)-th additional filling layer FL12_A may cover the (1-1)-th additional filling layer FL11_A. However, the number of additional filling layers stacked in the second recessed space P2 may be one or two or more in another embodiment.

In the present embodiment, the fourth filling layer FL4 and the second additional filling layer FL2_A may be disposed in the fourth recessed space P4. In other words, the fourth filling layer FL4 and the second additional filling layer FL2_A may be filled in the fourth recessed space P4. The fourth filling layer FL4 may be disposed below the third filling layers FL3 and may cover the third filling layers FL3 and the second lower surfaces L2. The second additional filling layer FL2_A may be disposed below the fourth filling layer FL4 and may cover the fourth filling layer FL4.

As an example of an embodiment of the inventive concept, the second additional filling layer FL2_A may include a (2-1)-th additional filling layer FL21_A and a (2-2)-th additional filling layer FL22_A, which are sequentially stacked in a direction opposite to the third direction DR3. The (2-1)-th additional filling layer FL21_A may cover the fourth filling layer FL4, and the (2-2)-th additional filling layer FL22_A may cover the (2-1)-th additional filling layer FL21_A. However, the number of additional filling layers stacked in the fourth recessed space P4 may be one or more than two in another embodiment.

According to the present embodiment, the second filling layer FL2 and the first additional filling layer FL1_A are provided in the second recessed space P2. Accordingly, the first filling layers FL1 may be covered by a plurality of layers. In addition, the fourth filling layer FL4 and the second additional filling layer FL2_A are provided in the fourth recessed space P4. Accordingly, the third filling layers FL3 may be covered by a plurality of layers. When filled by the filling layers FL1, FL2, FL3, FL4, FL1_A and FL2_A including the additional filling layers FL1_A and FL2_A, the substrate SUB may provide a more planarized surface to each of the components attached above the upper surface US and below the lower surface LS. Accordingly, the window WM (e.g., see FIG. 3) may have further improved surface quality, and the display device DD (e.g., see FIG. 3) may have further improved viewability as well.

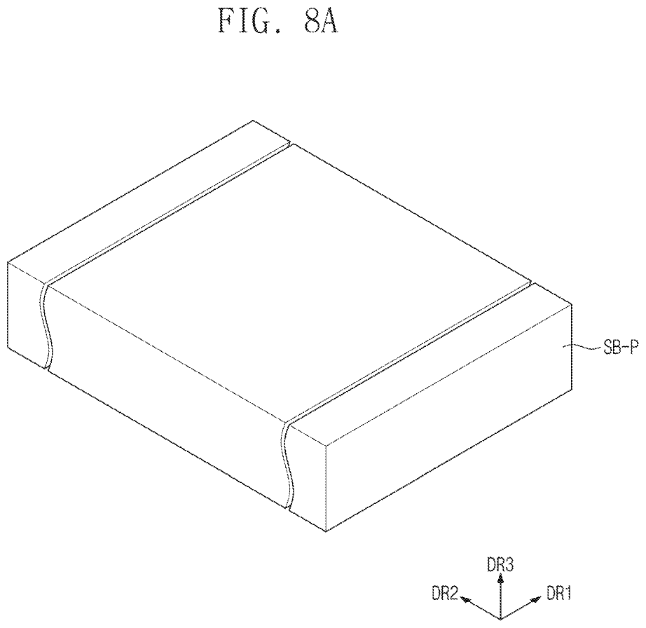

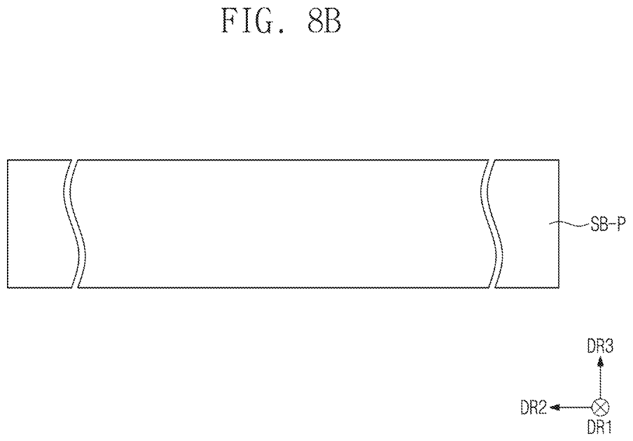

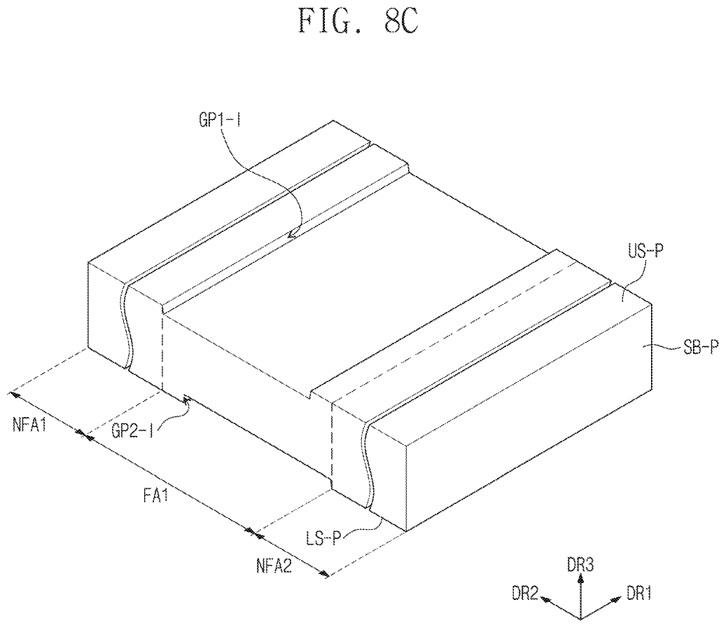

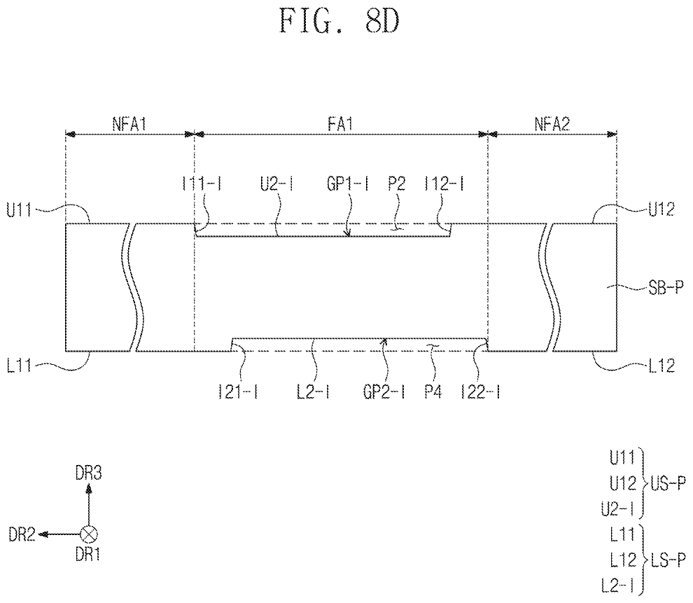

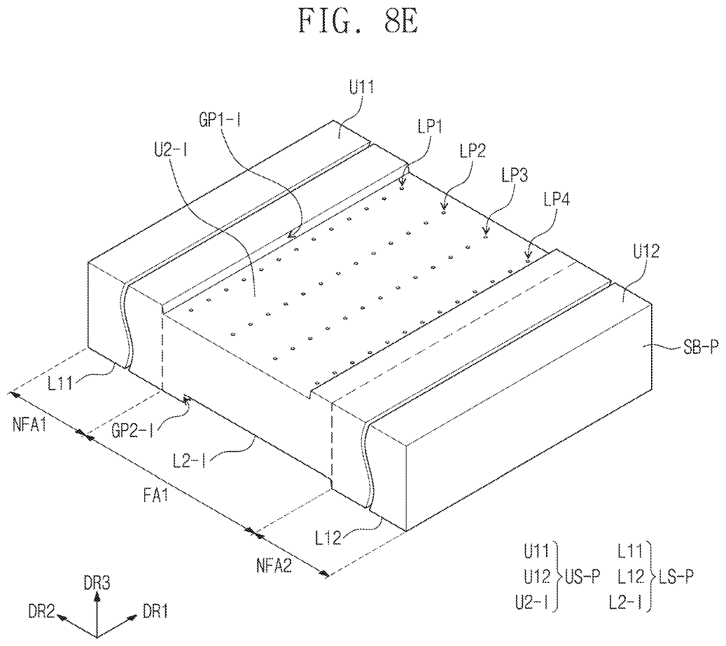

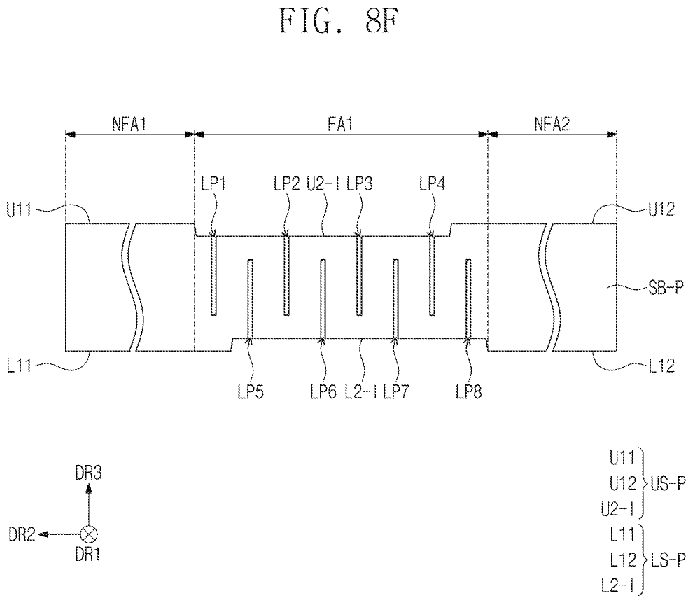

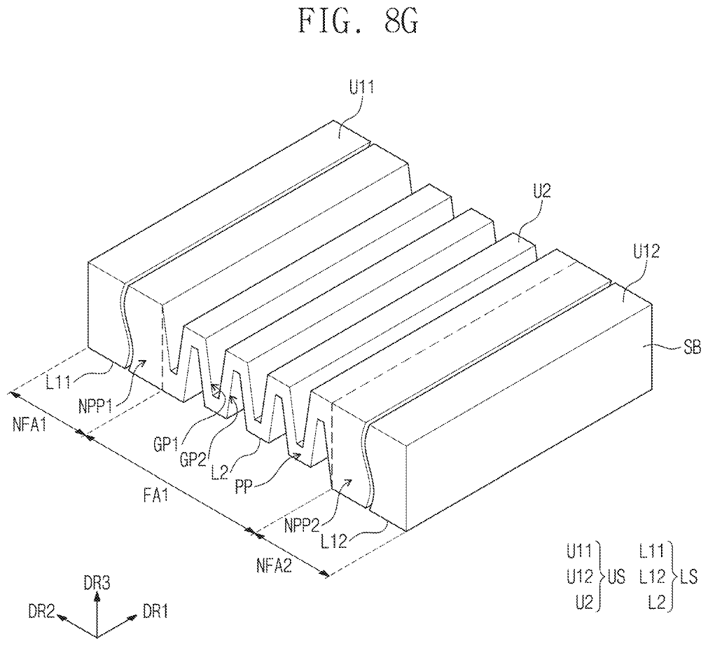

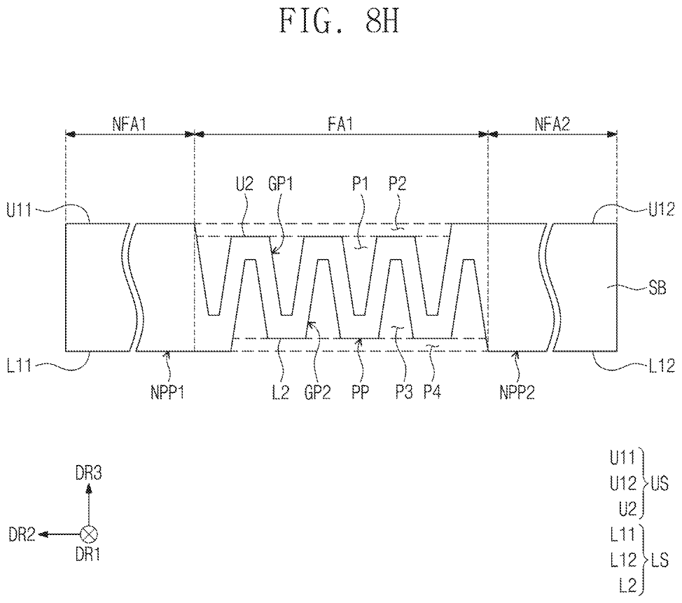

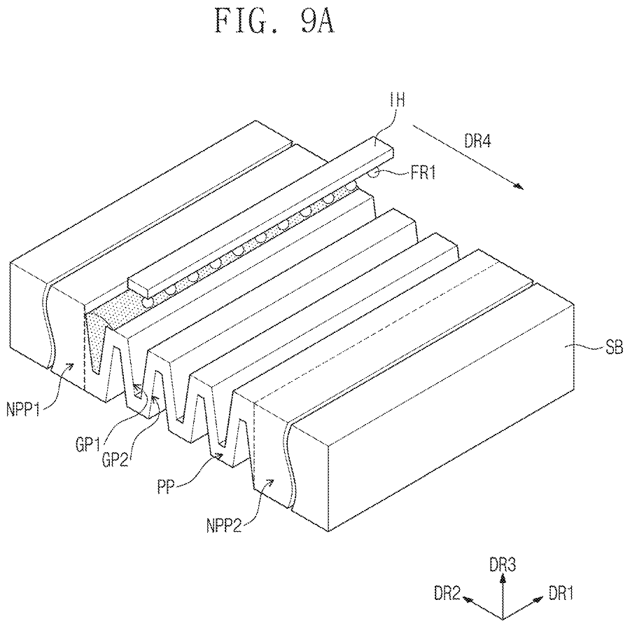

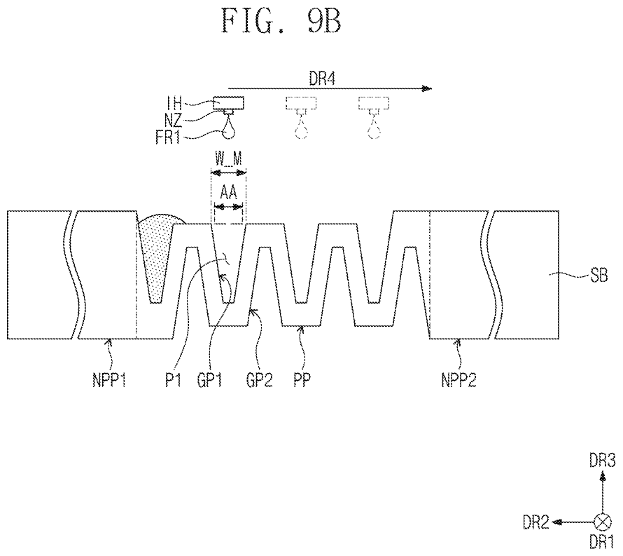

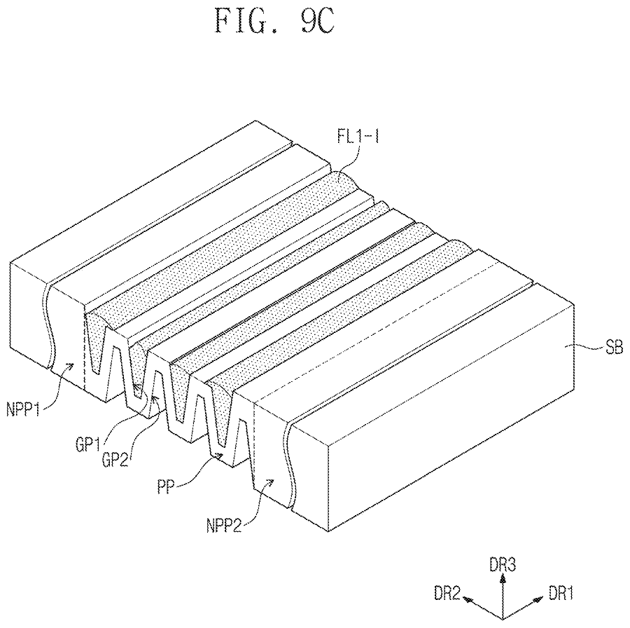

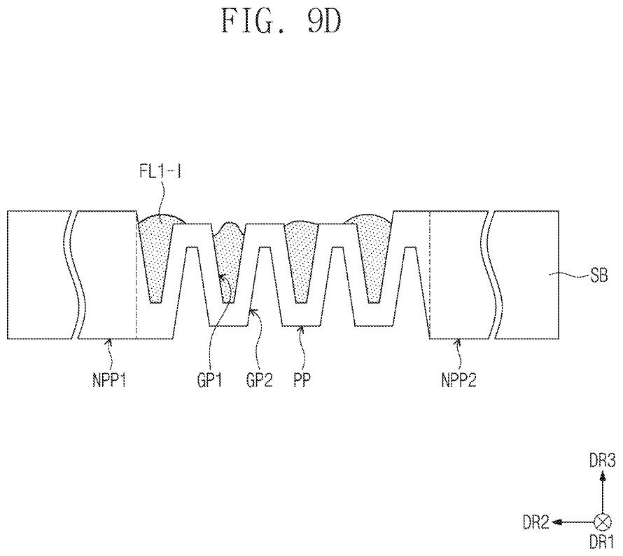

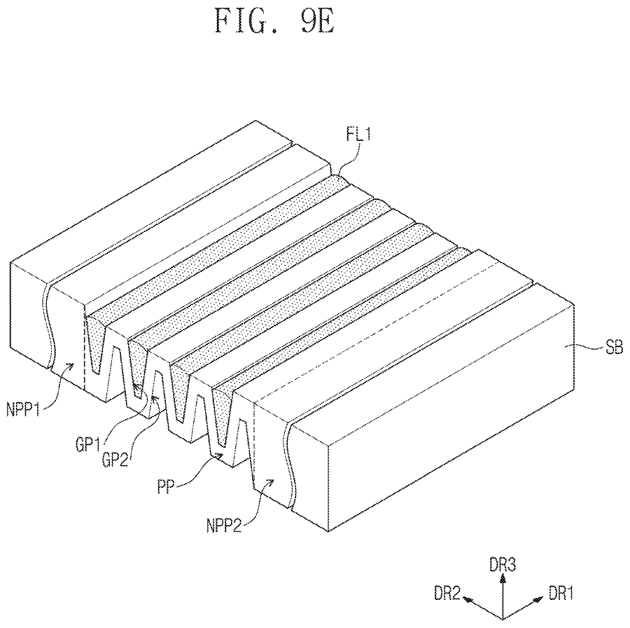

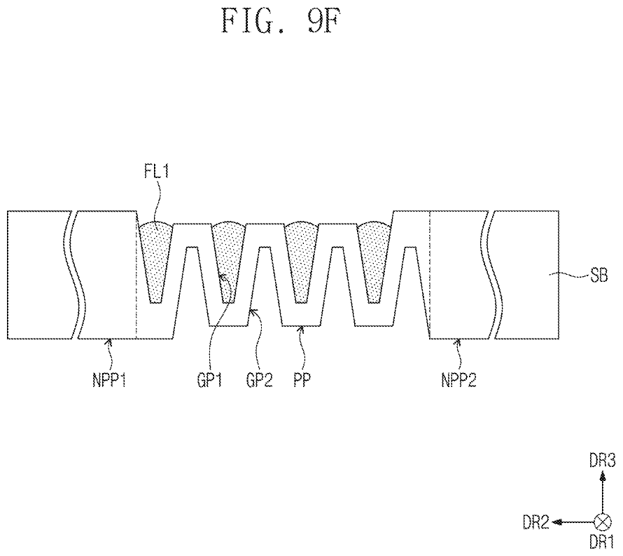

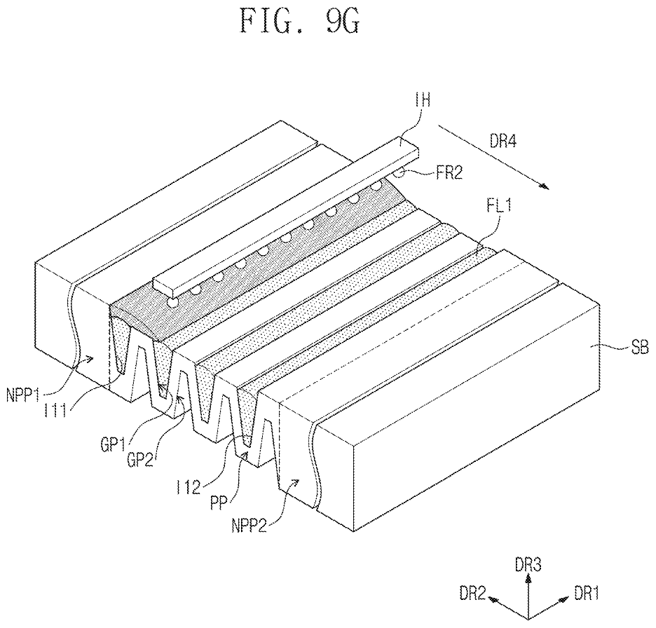

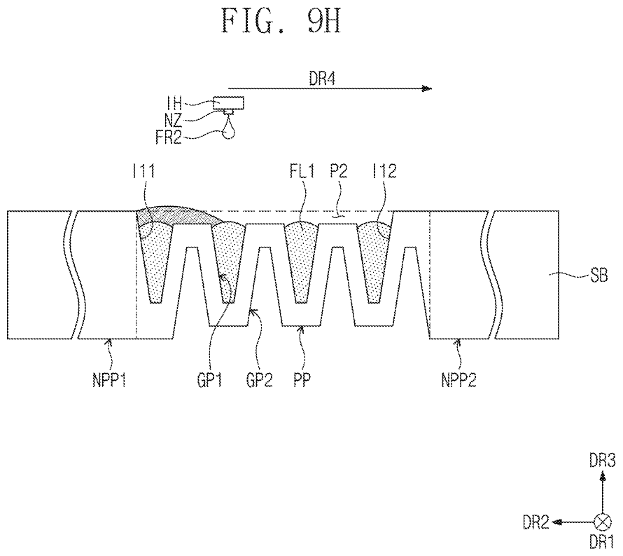

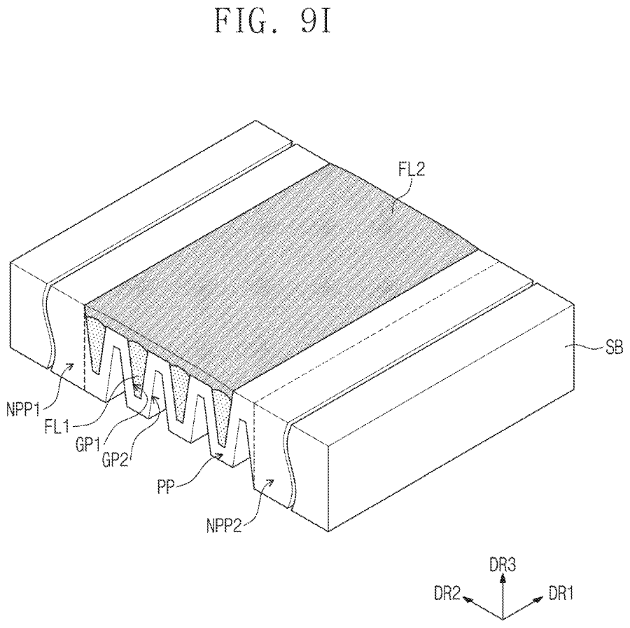

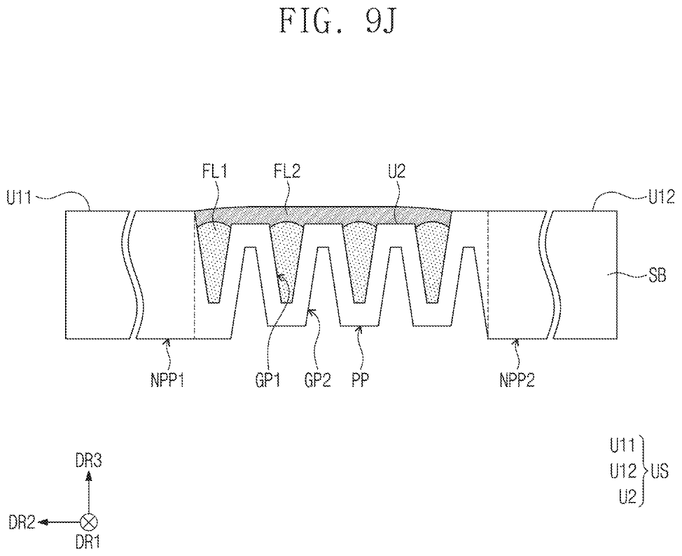

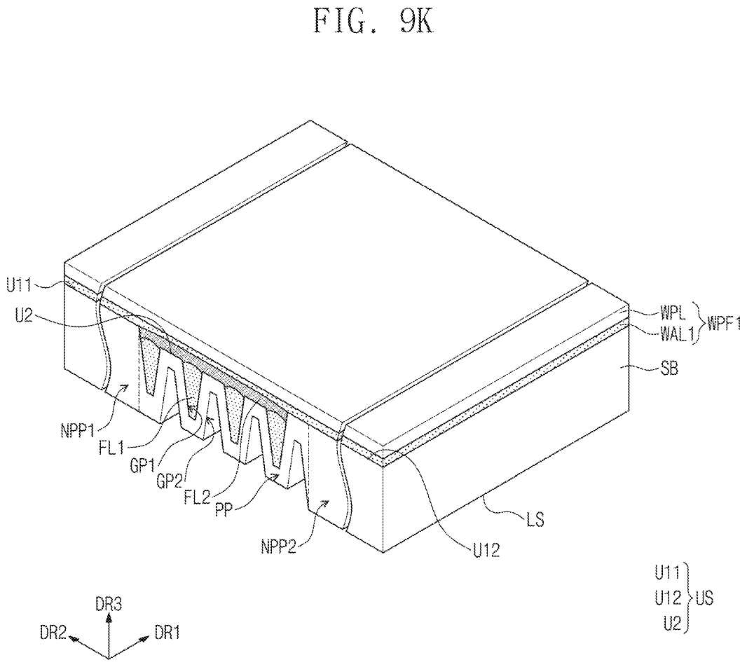

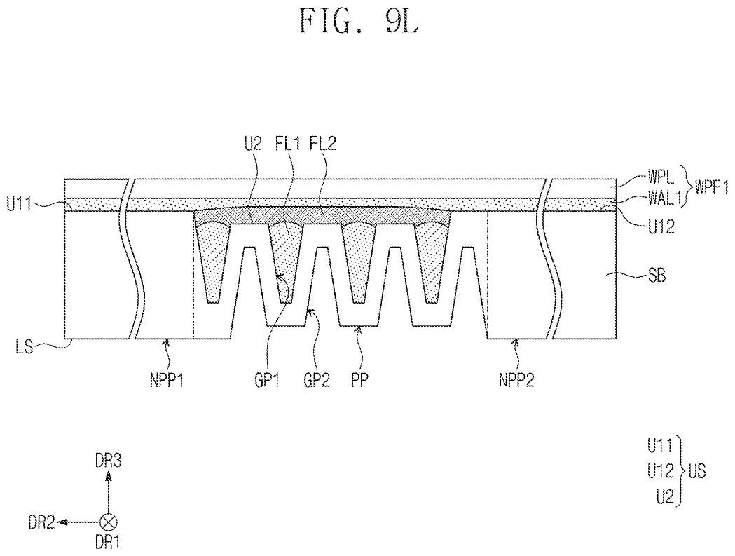

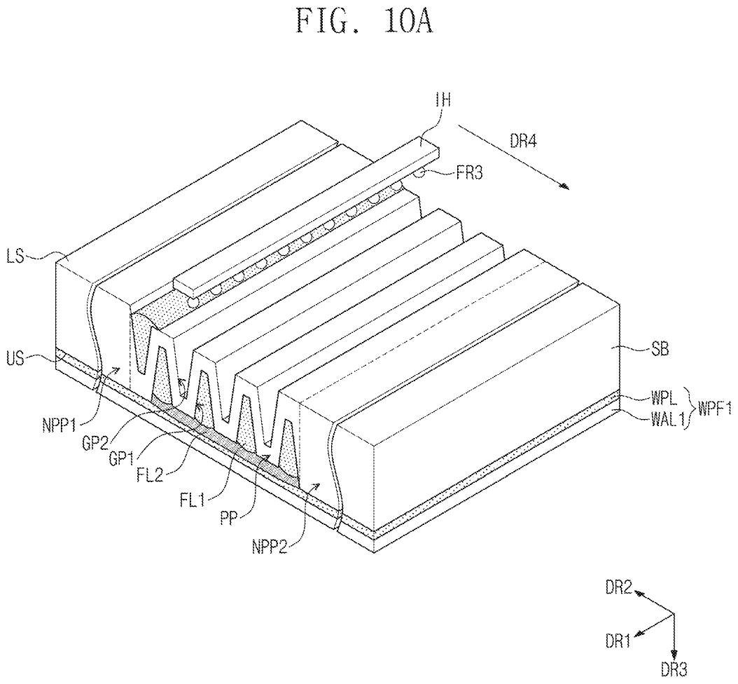

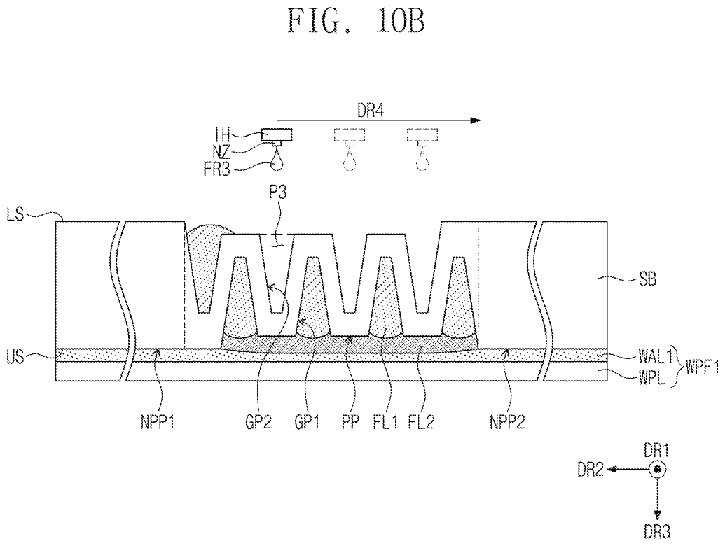

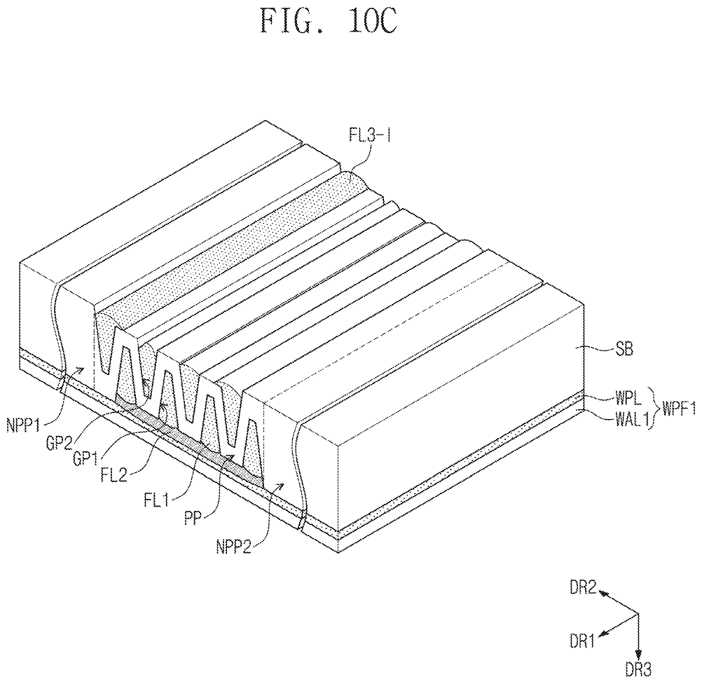

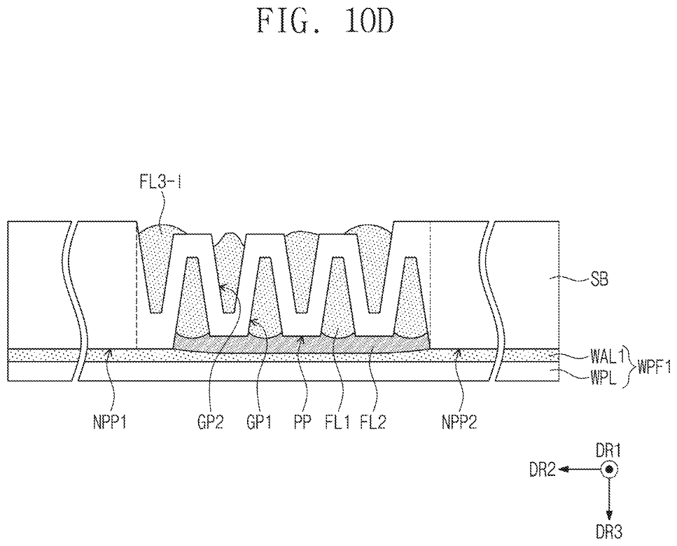

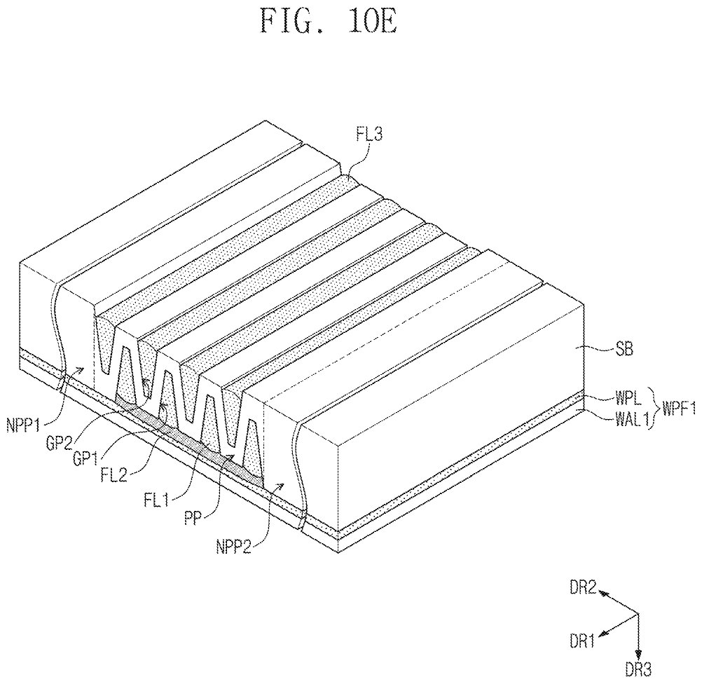

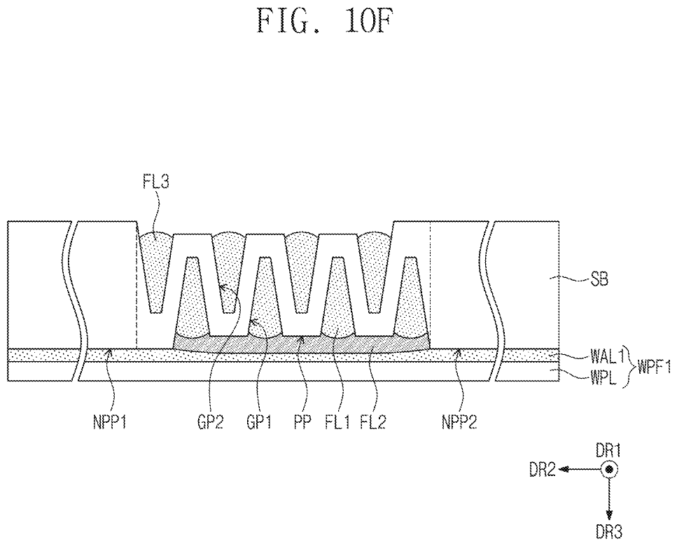

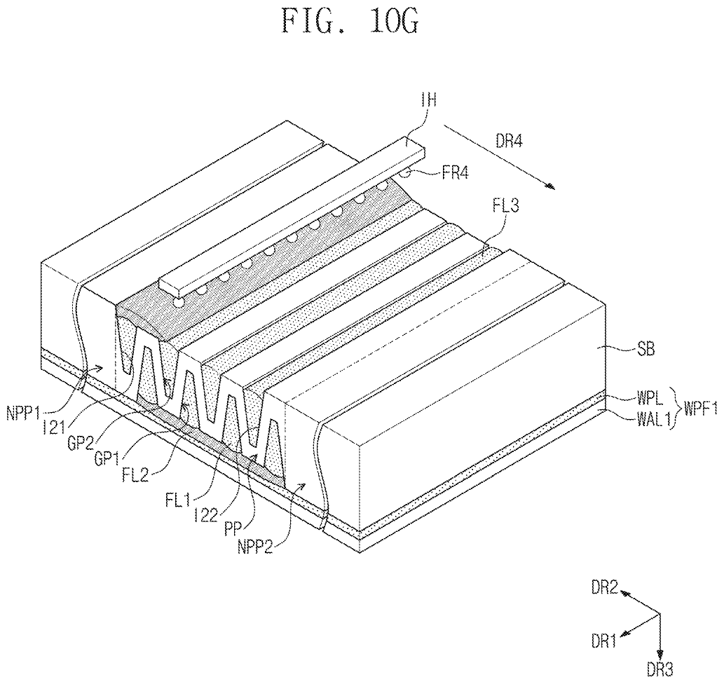

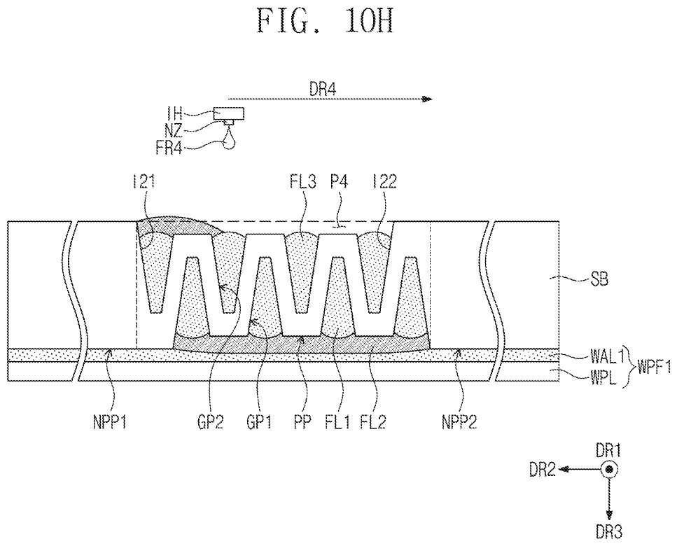

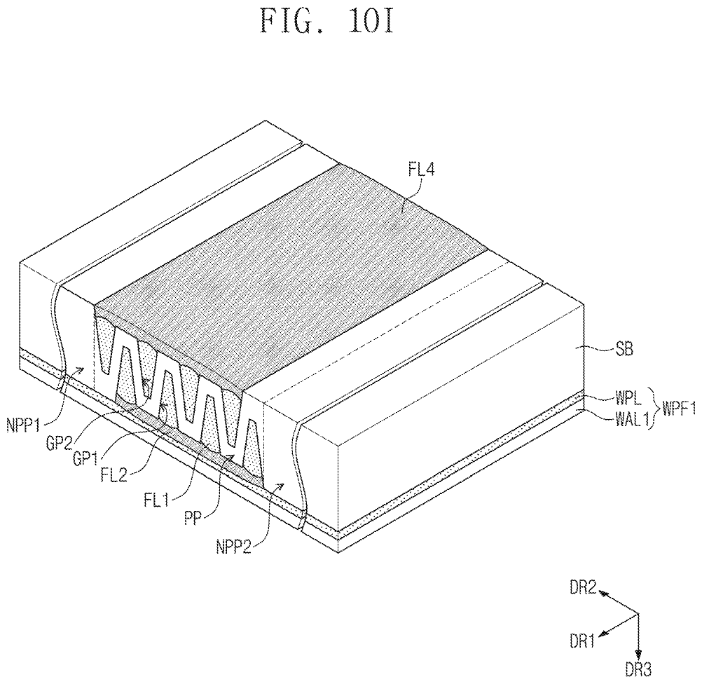

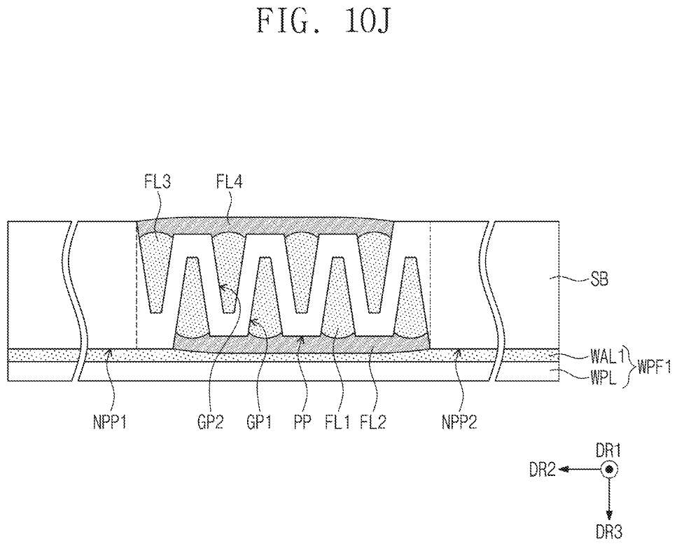

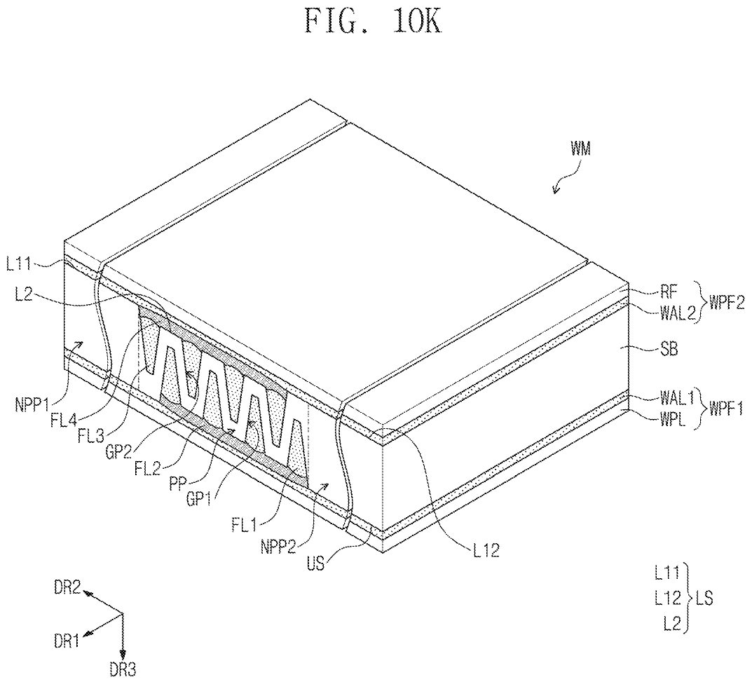

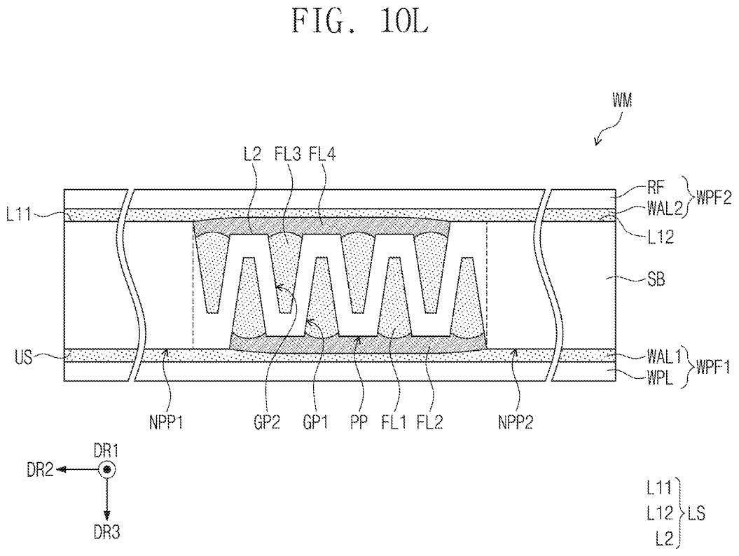

FIGS. 8A to 8H show operations included in a method of manufacturing a window according to an embodiment of the inventive concept. FIGS. 9A to 9I show operations included in a method of manufacturing a window according to an embodiment of the inventive concept. FIGS. 10A to 10I show operations included in a process of manufacturing a window according to an embodiment of the inventive concept.

More specifically, FIGS. 8A to 8H showing operations included in a process of manufacturing the substrate SB, in a process of manufacturing the window WM (e.g., see FIG. 10K). FIGS. 8A, 8C, 8E, and 8G are perspective views showing a manufacturing process of the substrate SB. FIGS. 8B, 8D, 8F, and 8H are cross-sectional views respectively corresponding to the perspective views of FIGS. 8A, 8C, 8E, and 8G.

Referring to FIGS. 8A and 8B, the method of manufacturing a window according to the present embodiment may include manufacturing a mother substrate SB-P. The mother substrate SB-P is a substrate for manufacturing the window WM (e.g., see FIG. 10K) and may correspond to a substrate before forming the groove patterns GP1 and GP2 (e.g., see FIG. 8G). The mother substrate SB-P may be a glass substrate, but may be made from a material different from glass in another embodiment.

Referring to FIGS. 8C and 8D, the method of manufacturing a window according to the present embodiment may include forming initial groove patterns GP1-I and GP2-I on the mother substrate SB-P. The initial groove patterns GP1-I and GP2-I may be formed, for example, through an etching process of the mother substrate SB-P. For example, the etching process of the mother substrate SB-P may be performed using an etching solution. The method used to provide an etching solution may be a spray method of spraying an etching solution or a dipping method of immersing the mother substrate SB-P in an etching solution. The etching solution may include an alkaline solution. However, the etching process method of the mother substrate SB-P is not limited thereto.

The initial groove patterns GP1-I and GP2-I may include a first initial groove pattern GP1-I and a second initial groove pattern GP2-I. The first initial groove pattern GP1-I may have a shape recessed from an upper surface US-P of the mother substrate SB-P, and the second initial groove pattern GP2-I may have a shape recessed from a lower surface LS-P of the mother substrate SB-P. The first and second initial groove patterns GP1-I and GP2-I may be formed to overlap the folding region FA1.

After the first initial groove pattern GP1-I is formed, the mother substrate SB-P may include (1-1)-th and (1-2)-th upper surfaces U11 and U12 overlapping the first and second non-folding regions NFA1 and NFA2, respectively, (1-1)-th and (1-2)-th initial inner surfaces I11-I and I12-I extending from the (1-1)-th and (1-2)-th upper surfaces U11 and U12, respectively, and a first initial bottom surface U2-I connecting the (1-1)-th and (1-2)-th initial inner surfaces I11-I and I12-I. The first initial groove pattern GP1-I may be defined by the (1-1)-th and (1-2)-th initial inner surfaces I11-I and I12-I and the first initial bottom surface U2-I.

The first initial groove pattern GP1-I may provide a first outer recessed space P2. The first outer recessed space P2 may correspond to the second recessed space P2 described above with reference to FIG. 5B. In addition, the first initial bottom surface U2-I may be referred to as a second initial upper surface U2-I, and may provide the second upper surfaces U2 described above with reference to FIG. 5B.

After the second initial groove pattern GP2-I is formed, the mother substrate SB-P may include (1-1)-th and (1-2)-th lower surfaces L11 and L12 overlapping the first and second non-folding regions NFA1 and NFA2, respectively, (2-1)-th and (2-2)-th initial inner surfaces I21-I and I22-I extending from the (1-1)-th and (1-2)-th lower surfaces L11 and L12, respectively, and a second initial bottom surface L2-I connecting the (2-1)-th and (2-2)-th initial inner surfaces I21-I and I22-I. The second initial groove pattern GP2-I may be defined by the (2-1)-th and (2-2)-th initial inner surfaces I21-I and I22-I and the second initial bottom surface L2-I.

The second initial groove pattern GP2-I may provide a second outer recessed space P4. The second outer recessed space P4 may correspond to the fourth recessed space P4 described above with reference to FIG. 5B. In addition, the second initial bottom surface L2-I may be referred to as a second initial lower surface L2-I, and may provide the second lower surfaces L2 described above with reference to FIG. 5B.

In the present embodiment, the depth of each of the first and second initial groove patterns GP1-I and GP2-I (or a depth of each of the first and second outer recessed spaces P2 and P4) may for example, be about 14 μm to about 20 μm.

In an embodiment, the first initial groove pattern GP1-I and the second initial groove pattern GP2-I may overlap in some regions. In one embodiment, the first initial groove pattern GP1-I may be formed relatively closer to the first non-folding region NFA1 than the second initial groove pattern GP2-I. Also, the second initial groove pattern GP2-I may be formed relatively closer to the second non-folding region NFA2 than the first initial groove pattern GP1-I. However, the embodiment of the inventive concept is not limited thereto, and the first initial groove pattern GP1-I may be disposed to be closer to the second non-folding region NFA2 and the second initial groove pattern GP2-I may be disposed to be closer the first non-folding region NFA1.

Referring to FIGS. 8E to 8H, the method of manufacturing a window according to the present embodiment may include forming the groove patterns GP1 and GP2 on the mother substrate SB-P.

First, referring to FIGS. 8E and 8F, laser patterns LP1 to LP8 may be formed on the mother substrate SB-P. The laser patterns LP1 to LP8 may be formed by irradiating both surfaces of the mother substrate SB-P with a light source, e.g., an microwave pulse laser. The laser patterns LP1 to LP8 may each be provided to correspond to positions where the first and second groove patterns GP1 and GP2 (e.g., see FIG. 5B) of FIGS. 8G and 8H are to be formed.

As shown in 8E and 8F, first to fourth laser patterns LP1, LP2, LP3, and LP4 may be formed on the second initial upper surface U2-I of the mother substrate SB-P. The first to fourth laser patterns LP1, LP2, LP3, and LP4 may be arranged along the second direction DR2 perpendicular to the folding axis FX1 (e.g., see FIG. 5A). The first to fourth laser patterns LP1, LP2, LP3, and LP4 may each include patterns arranged in the first direction DR1 parallel to the folding axis FX1 (e.g., see FIG. 5A). As an example of an embodiment of the inventive concept, the patterns may each have a circular shape when viewed on a plane.

As shown in FIG. 8F, the first to fourth laser patterns LP1, LP2, LP3, and LP4 each have a shape recessed from the second initial upper surface U2-I of the mother substrate SB-P. As an example of an embodiment of the inventive concept, the first to fourth laser patterns LP1, LP2, LP3, and LP4 may each be a cylindrical groove.

As further shown in FIG. 8F, fifth to eighth laser patterns LP5, LP6, LP7, and LP8 may also be formed on the second initial lower surface L2-I of the mother substrate SB-P. The formation of the fifth to eighth laser patterns LP5, LP6, LP7, and LP8 may be similar to formation of the first to fourth laser patterns LP1, LP2, LP3, and LP4, except the fifth to eighth laser patterns LP5, LP6, LP7, and LP8 have a shape recessed from the second initial lower surface L2-I.

The microwave pulse laser may be a picosecond laser or a femtosecond laser. The picosecond laser has a wavelength period in picosecond units, and a femtosecond laser has a wavelength period in femtosecond units. In forming the laser patterns LP1 to LP8, the laser patterns LP1 to LP8 may be formed in a deep and narrow groove shape, using the microwave pulse laser. In addition, with use of the microwave pulse laser, even when the laser process is performed, impact to the mother substrate SB-P is small, so that cracks or other defects are not likely to be formed around the laser patterns LP1 to LP8.

At this stage of the method, changes in appearance of the mother substrate SB-P by the laser may not be easily observed. The laser patterns LP1 to LP8 may be visually observed, for example, using a high-magnification microscope or the like.

Referring to FIGS. 8G and 8H, the method includes forming the groove patterns GP1 and GP2 from the laser patterns LP1 to LP8 (e.g., see FIG. 8F). The mother substrate SB-P (e.g., see FIG. 8F) on which the laser patterns LP1 to LP8 (e.g., see FIG. 8F) are formed may be etched to provide groove patterns GP1 and GP2 on the substrate SUB. The first groove patterns GP1 are formed from the first to fourth laser patterns LP1, LP2, LP3, and LP4 (e.g., see FIG. 8F), and the second groove patterns GP2 may be formed from the fifth to eighth laser patterns LP5, LP6, LP7, and LP8 (e.g., see FIG. 8F). The first groove patterns GP1 and the second groove patterns GP2 may each have a stripe shape extending along the first direction DR1. In addition, the first and second groove patterns GP1 and GP2 may be alternately arranged along the second direction DR2 in a zig-zag pattern.

The etching process of etching the mother substrate SB-P (e.g., see FIG. 8F) may be performed, for example, using an etching solution containing an alkaline solution. When the etching process is performed using such an etching solution, the laser patterns LP1 to LP8 (see FIG. 8f) of the mother substrate SB-P (see FIG. 8f) may be anisotropically etched. As the mother substrate SB-P (see FIG. 8F) is etched around the laser patterns LP1 to LP8 (see FIG. 8F), stripe-shaped groove patterns GP1 and GP2 are formed. Accordingly, the substrate SB includes a first non-patterned portion NPP1, a second non-patterned portion NPP2, and a patterned portion PP. The first and second inner recessed spaces P1 and P3 may each be provided on the substrate SB by the first and second groove patterns GP1 and GP2. The first and second inner recessed spaces P1 and P3 may each correspond to the first and third recessed spaces P1 and P3 described above with reference to FIG. 5B.

Although FIG. 8E shows a structure in which a plurality of laser patterns LP1 to LP4 are formed in one row to form each of the groove patterns GP1 and GP2, the structure is not limited thereto. In one embodiment, the laser patterns LP1 to LP4 may be provided in a plurality of rows according to the width of each of the groove pattern GP1 or GP2.

Thereafter, a process of chemically strengthening the substrate SB on which the groove patterns GP1 and GP2 are formed may be performed. Through the chemical strengthening process, the surface of the substrate SB, which has weakened through irradiation of the laser, may be strengthened. In addition, through the chemical strengthening process, the substrate SB may have greater impact resistance and a refractive index of the substrate SB may be regulated.

Thereafter, a process of heat-treating the chemically strengthened substrate SB may be performed.

FIGS. 9A to 10L show operations included in a process of manufacturing the window WM from the substrate SB on which the groove patterns GP1 and GP2 are formed. FIGS. 9A, 9C, 9E, 9G, 9I, 9K, 10A, 10C, 10E, 10G, 10I, and 10K are perspective views showing a process of manufacturing a window. FIGS. 9B, 9D, 9F, 9H, 9I, 10B, 10D, 10F, 10H, and 10Il are cross-sectional views respectively corresponding to the perspective views of FIGS. 9A, 9C, 9E, 9G, 9I, 9K, 10A, 10C, 10E, 10G, 10I, and 10K.

In the present embodiment, in the method of manufacturing a window, a plurality (e.g., four) filling processes may be performed. First and second filling processes are shown in FIGS. 9A to 9J.

Referring to FIGS. 9A to 9F, the method of manufacturing a window according to the present embodiment may include forming first filling layers FL1. The first filling layers FL1 may be formed through a process of spraying a first filling resin FR1 using, for example, an inkjet method (a first filling process).

As shown in FIGS. 9A and 9B, the process of spraying the first filling resin FR1 may use an inkjet head IH. The inkjet head IH may have a structure elongated in a direction to which the first groove patterns extend (e.g., in the first direction DR1). A plurality of spray nozzles NZ may be disposed in the inkjet head IH. The spray nozzles NZ may be spaced apart from each other in the first direction DR1.

The inkjet head IH may spray the first filling resin FR1 while moving in one direction (e.g., a fourth direction DR4 opposite to the second direction DR2). The first filling resin FR1 may be sprayed at every position corresponding to the first groove patterns GP1. The amount of the first filling resin FR1 ejected from each spray nozzle NZ per unit time may be the same. As a result, the ejection amount per unit time of the first filling resin FR1 sprayed on each of the first groove patterns GP1 may be the same.

In the present embodiment, region AA where the first filling resin FR1 may be a region corresponding to about 70% to about 80% of an upper end of the first groove pattern GP1 forming a maximum width W_M of the first groove pattern GP1.

When a separate recessed space is not provided on the first groove patterns GP1, a method of spraying the first filling resin FR1 in a region corresponding to about 30% of the upper end of the first groove pattern GP1 forming the maximum width of the first groove pattern GP1 may be used in order to prevent the first filling resin FR1 from overflowing from the first groove pattern GP1. In this case, spraying the first filling resin FR1 may be repeated several times or the spraying frequency (e.g., the number of sprayings per second) may be raised to prevent the first filling resin FR1 from being unfilled, resulting in longer manufacturing time and shorter equipment life.

According to the present embodiment, because the first outer recessed space P2 is provided on the first groove patterns GP1, a step that is externally visible may not be provided on a surface of a final window WM (e.g., see FIG. 10K). This may be the case even when the first filling resin FR1 partially overflows from the first groove pattern GP1. Accordingly, in the present embodiment, the first filling resin FR1 may be provided in a greater width than in a case where no separate recessed space is provided on the first groove patterns GP1. Thus, spraying of the first filling resin FR1 several times may not been performed, and also the spraying frequency (e.g., the number of sprayings per second) may not be increased. This may substantially reduce manufacturing time and prevent a reduction in equipment life.

The first filling resin FR1 may be a low-viscosity liquid crystal resin. In an embodiment, the first filling resin FR1 may have a viscosity of, for example, about 20 cPs or less. The first filling resin FR1 may have a different viscosity in another embodiment. Also, the first filling resin FR1 may have substantially the same refractive index as the substrate SB.

In the present embodiment, having substantially the same refractive index may correspond to a case where the difference in refractive index between the first filling resin FR1 and the substrate SUB is, for example, about 0.003 or less.

As shown in FIGS. 9A to 9D, the first filling resin FR1 applied by spraying may form first preliminary filling layers FL1-I filling in the first groove patterns GP1 (or first inner recessed spaces P1).

Then, as shown in FIGS. 9C to 9F, a process of curing the first filling resin FR1 (e.g., see FIG. 9B) filled in the first groove patterns GP1 (e.g., the first preliminary filling layers FL1-I) may be performed to form the first filling layers FL1.

In the present embodiment, the curing process of the first preliminary filling layers FL1-I may be performed after a predetermined period of time has passed after completion of the spraying process of the first filling resin FR1 (e.g., see FIG. 9B). The predetermined period of time may be provided for surfaces of the first preliminary filling layers FL1-I to be relatively flat before curing. Thus, after curing is completed, the first filling layers FL1 may be provided to have relatively flat surfaces.

In contrast, when the curing process is performed right after the spraying process of the first filling resin FR1 (see FIG. 9B) is completed, the first preliminary filling layers FL1-I may be cured to have convex surfaces. Thus, after curing is completed, the first filling layers FL1 may be provided to have convex surfaces.

Referring to FIGS. 9G to 9J, the method of manufacturing a window according to the present embodiment may include forming a second filling layer FL2. The second filling layer FL2 may be formed through a process of spraying a second filling resin FR2 using, for example, an inkjet method (and thus may be referred to as a second filling process). The second filling resin FR2 may include the same material as the first filling resin FR1 (e.g., see FIG. 9B) or may include a different material.

As shown in FIGS. 9G and 9H, the spraying process of the second filling resin FR2 may use the inkjet head IH having spray nozzles NZ. The inkjet head IH may spray the second filling resin FR1 while moving in one direction (e.g., a fourth direction DR4). Unlike the first filling resin FR1 (e.g., see FIG. 9B), spraying of the second filling resin FR2 may be continuously performed in a position corresponding to the first outer recessed space P2. For example, the inkjet head IH may continuously spray the second filling resin FR2 while moving from a position corresponding to the (1-1)-th inner surface I11 to a position corresponding to the (1-2)-th inner surface I12. The viscosity and refractive index of the first filling resin FR1 (e.g., see FIG. 9B) may also apply to the second filling resin FR2.

As shown in FIGS. 9G to 9J, the second filling resin FR2 may fill the first outer recessed space P2 and cover the first filling layers FL1. The second filling resin FR2, filled in the first outer recessed space P2, may form the second filling layer FL2 through, for example, a curing process. As an example of an embodiment of the inventive concept, the curing process of the second filling resin FR2 may also be performed after a predetermined period of time has passed after completion of the spraying process, like the curing process of the first filling resin FR1.

The second filling layer FL2 may continuously extend from the first filling layer disposed on one side of the first filling layers FL1 and closest to the first non-pattern portion NPP1 to the first filling layer disposed on the other side of the first filling layers FL1 and closest to the second non-pattern portion NPP2.

In performing the process of forming the substrate SB, process errors may be generated during the process of forming the first groove patterns GP1 described above with reference to FIGS. 8E to 8H. For example, there may be a predetermined error between the pitch of the actually formed first groove patterns GP1 and a preset pitch. For example, one or more of the actually formed first groove patterns GP1 may be formed at positions different from those of the preset first groove patterns GP1. In this case, in performing the inkjet process of the first filling resin FR1, landing positions of the first filling resin FR1 may not match the actual positions of the first groove patterns GP1 (e.g., see FIG. 9B). The first filling resin FR1 may thus land outside the first groove patterns GP1. For example, the first filling resin FR1 may land onto the second upper surfaces U2, and some of the first groove patterns GP1 may not be sufficiently filled with the first filling resin FR1 (e.g., see FIG. 9B). This may result in a step formed between the second upper surfaces U2 and the first filling layers FL1. The step may have a height, for example, of about 16 μm to about 23 μm, which may be visible to users.

Alternatively, a process error may be generated even in the process of filling the first filling resin FR1 described above with reference to FIGS. 9A and 9B. For example, the actual landing position of the first filling resin FR1 may not match the predetermined landing position of the first filling resin FR1. Similarly, in this case, the first filling resin FR1 may land outside of the first groove patterns GP1, and a step visible to users may be formed between the second upper surfaces U2 and the first filling layers FL1.

According to an embodiment of the inventive concept, a separate recessed space P2 is provided on the first groove patterns GP1 in the substrate SB. Accordingly, even when the first filling resin FR1 lands on the second upper surfaces U2 due to the process errors, the first filling resin FR1 may not protrude further than the (1-1)-th and (1-2)-th upper surfaces U11 and U12. In addition, the amount of the filled first filling resin FR1 may be different for each of the first groove patterns GP1. Thus, the first filling layers FL1 may be formed to have different heights, thereby forming a step between the first filling layers FL1 and the second upper surfaces U2. However, this step may be covered by the second filling layer FL2 to provide a relatively flat surface to components disposed on the substrate SB. In some cases, a step of about 5 μm or less may be formed in the second filling layer FL2, and this may not be visible to users.

In addition, according to an embodiment of the inventive concept, as described above with reference to FIGS. 9A and 9B, during the inkjet process of the first filling resin FR1, spraying the first filling resin FR1 may be performed in a relatively wide region to prevent insufficient filling of the first filling resin FR1. Accordingly, the size of a step formed between the second upper surfaces U2 and the first filling layers FL1 may be reduced, so that the second filling layer FL2 may provide a more planarized surface to components disposed on the substrate SB.

Therefore, according to an embodiment of the inventive concept, even when process errors are generated, the formation of visible interference fringes by the first groove patterns GP1 may be prevented. Thus, a window WM (e.g., see FIG. 10K) having improved surface quality and improved process reliability may be provided. This may result in providing a display device (e.g., display device DD in FIG. 3) having improved viewability.

Then, referring to FIGS. 9K and 9L, the method of manufacturing a window according to the present embodiment may include forming a first window protection film WPF1 on the upper surface US of the substrate SB. The first window protection film PF1 may be bonded to the substrate SB on which the first filling layers FL1 and the second filling layers FL2 are formed. The first window protection film WPF1 may include a window protection layer WPL and a first window adhesive layer WAL1 bonding the window protection layer WPL and the substrate SB.

According to the present embodiment, a step of about 5 μm or less may be formed between the (1-1)-th and (1-2)-th upper surfaces U11 and U12 of the substrate SB and the second filling layer FL2. Therefore, when the first window protection film WPF1 is bonded to the substrate SB, air bubbles may be prevented from forming between the first window adhesive layer WAL1 and the substrate SB. As a result, the first groove patterns GP1 may be prevented from being viewed.

Thereafter, the substrate SB to which the first window protection film PF1 is bonded may be turned over so that the first window protection film WPF1 is disposed below the substrate SB. In this case, the substrate SB may be provided so that the lower surface LS is disposed above the upper surface US.

Thereafter, the method of manufacturing a window may perform the remaining two filling processes. FIGS. 10A to 10J show third and fourth filling processes.

Referring to FIGS. 10A to 10F, the method of manufacturing a window according to the present embodiment may include forming third filling layers FL3. The third filling layers FL3 may be formed through a process of spraying a third filling resin FR3 using, for example, an inkjet method (a third filling process). In an embodiment, the third filling resin FR3 may include the same material as the first filling resin FR1 (e.g., see FIG. 9B).

As shown in FIGS. 10A and 10B, the spraying process of the third filling resin FR3 may be performed in a manner similar to the spraying process of the first filling resin. The spraying process of the third filling resin FR3 may use the inkjet head IH including the spray nozzles NZ, and the inkjet head IH may spray the third filling resin FR1 while moving in one direction (e.g., a fourth direction DR4). The third filling resin FR3 may be sprayed at every position corresponding to the second groove patterns GP2.

As shown in FIGS. 10A to 10D, the third filling resin FR3 subjected to spraying may form third preliminary filling layers FL3-I filling each of the second groove patterns GP2 (or second inner recessed spaces P3).

Then, as shown in FIGS. 10C to 10F, a process of curing the third filling resin FR3 (e.g., see FIG. 10B) filled in the second groove patterns GP2 (e.g., the third preliminary filling layers FL3-I) may be performed to form the third filling layers FL3. Similar to the curing process of the first preliminary filling layers FL1-I (e.g., see FIG. 9D), the curing process of the third preliminary filling layers FL3-I may also be performed after a predetermined period of time has passed after completion of the spraying process.

Then, referring to FIGS. 10G to 10J, the method of manufacturing a window according to the present embodiment may include forming a fourth filling layer FL4. The fourth filling layer FL4 may be formed through a process of spraying the fourth filling resin FR4, for example, using an inkjet method (a fourth filling process). In an embodiment, the fourth filling resin FR4 may include the same material as the second filling resin FR2 (e.g., see FIG. 9H).

As shown in FIGS. 10G and 10H, the spraying process of the fourth filling resin FR4 may use the inkjet head IH including spray nozzles NZ, and the inkjet head IH may spray the fourth filling resin FR4 while moving in one direction (e.g., a fourth direction DR4). Spraying of the fourth filling resin FR4 may be continuously performed at a position corresponding to the second outer recessed space P4. For example, the inkjet head IH may continuously spray the fourth filling resin FR4 while moving from a position corresponding to the (2-1)-th inner surface I21 to a position corresponding to the (2-2)-th inner surface I22.

As shown in FIGS. 10G to 10J, the fourth filling resin FR4 subjected to spraying may fill the second outer recessed space P4 and cover the third filling layers FL3. The fourth filling resin FR4 filled in the second outer recessed space P4 may form the fourth filling layer FL4 through a curing process. As an example of an embodiment of the inventive concept, the curing process of the fourth filling resin FR4 may also be performed after a predetermined period of time has passed after the completion of the spraying process, like the curing process of the first filling resin FR1 (e.g., see FIG. 9B).

The fourth filling layer FL4 may continuously extend from the third filling layer (disposed on one side of the third filling layers FL3 and closest to the first non-pattern portion NPP1) to the third filling layer disposed on the other side of the third filling layers FL3 and closest to the second non-pattern portion NPP2.

During the process of forming the substrate SB, process errors may be generated during formation of the second groove patterns GP2, as described in FIGS. 8E to 8H, and/or process errors may also be generated in the process of filling the third filling resin FR3, as described above in FIGS. 10A and 10B. Accordingly, the third filling resin FR3 may land outside of the second groove patterns GP2 and a step visible to users may be formed between the second lower surfaces L2 and the third filling layers FL3.

According to an embodiment of the inventive concept, the separate recessed space P4 is provided on the second groove patterns GP2 in the substrate SB. Thus, a step may be formed between the third filling layers FL3 and the second lower surfaces L2. But even though such a step may be formed, the step may be covered by the fourth filling layer FL4 to provide a relatively flat surface to components disposed on the substrate SB. A step of about 5 μm or less may be formed in the fourth filling layer FL4, and this may not be visible to users. In addition, spraying the third filling resin FR3 may be performed in a relatively wide region, so that the fourth filling layer FL4 may provide a more planarized surface to components disposed below the substrate SB.

Therefore, according to an embodiment of the inventive concept, even when the process errors are generated, the formation of interference fringes by the second groove patterns GP2 may be prevented. Thus, a window WM (e.g., see FIG. 10K) having improved surface quality and improved process reliability may be provided. As a result, the display device DD (e.g., see FIG. 3) may have improved viewability.

Then, referring to FIGS. 10K and 10L, the method of manufacturing a window according to the present embodiment may include forming a second window protection film WPF2 on the lower surface LS of the substrate SB. The second window protection film WPF2 may be bonded to the substrate on which the third filling layers FL3 and the fourth filling layers FL4 are formed. The second window protection film WPF2 may include a release paper film RF and a second window adhesive layer WAL2 bonding the release paper film RF and the substrate SB.

According to the present embodiment, a step of about 5 μm or less may be formed between the (1-1)-th and (1-2)-th lower surfaces L11 and L12 of the substrate SB and the fourth filling layer FL4. Therefore, when the second window protection film WPF2 is bonded to the substrate SB, air bubbles may be prevented from forming between the second window adhesive layer WAL2 and the substrate SB. As a result, the second groove patterns GP2 may not be visible.

Accordingly, the window WM may be formed. When the substrate SB to which the second window protection film WPF2 is bonded is turned over so that the second window protection film WPF2 is disposed below the substrate SB, the upper surface US of the substrate SB may correspond to the window (e.g., WM of FIG. 4) disposed above the lower surface LS of the substrate SB. Thereafter, the release paper film RF may be removed, and attaching the second window adhesive layer WAL2 in the window WM and the components disposed below the window WM may be performed to manufacture a display device DD (e.g., see FIG. 3) including a window.

According to one or more of the aforementioned embodiments of the inventive concept, a window includes a plurality of groove patterns that promote improved folding properties of the window and its display device. In this case, the window may include groove patterns recessed from an upper surface and groove patterns recessed from a lower surface, and accordingly may have excellent folding properties.

According to one or more of the aforementioned embodiments of the inventive concept, the window may include first filling layers in groove patterns and may include a second filling layer covering the first filling layers. In this case, the window may include recessed upper surfaces in a folding region and provide a space in which the second filling layer may be disposed. Accordingly, a window is provided to have improved surface quality, and may prevent the visible formation of interference fringes caused by groove patterns. As a result, a display device having improved viewability may be provided.

According to one or more of the aforementioned embodiments of the inventive concept, in a method of manufacturing a window, a printing process of a second filling layer is performed after a printing process of first filling layers. As a result, a window having excellent folding properties, improved surface quality, and improved process reliability may be manufactured.

Although the present disclosure has been described with reference to a preferred embodiment of the inventive concept, it will be understood that the inventive concept should not be limited to these preferred embodiments but various changes and modifications may be made by those skilled in the art without departing from the spirit and scope of the present disclosure. Hence, the technical scope of the present disclosure is not limited to the detailed descriptions in the specification but should be determined only with reference to the claims. The embodiments may be combined to form additional embodiments.

What is claimed is:

1. A window comprising:
a substrate that includes an upper surface and a lower surface opposing the upper surface, the substrate including a pattern portion including first groove patterns recessed from the upper surface and second groove patterns recessed from the lower surface and alternately arranged with the first groove patterns, and a non-pattern portion adjacent to the pattern portion;
first filling layers each disposed in a respective one of the first groove patterns;
a second filling layer covering the first filling layers;
third filling layers each disposed in a respective one of the second groove patterns; and
a fourth filling layer covering the third filling layers, wherein a height of the pattern portion is less than a height of the non-pattern portion.

2. The window of claim 1, wherein:
the upper surface comprises a first upper surface in the non-pattern portion and a second upper surface in the pattern portion, and
the second upper surface is disposed to be more recessed than the first upper surface.

3. The window of claim 2, wherein the second filling layer is disposed in a step formed between the first upper surface and the second upper surface.

4. The window of claim 2, wherein the second upper surface is recessed by about 14 μm to about 20 μm from a plane in which the first upper surface extends.

5. The window of claim 1, wherein the second filling layer continuously extends from the first filling layer disposed on one side among the first filling layers to the first filling layer disposed on another side among the first filling layers.

6. The window of claim 1, wherein:
the lower surface comprises a first lower surface in the non-pattern portion and a second lower surface in the pattern portion,
the second lower surface is disposed to be more recessed than the first lower surface, and
the fourth filling layer is disposed in a step formed between the first lower surface and the second lower surface.

7. The window of claim 1, wherein:
the non-pattern portion comprises a first non-pattern portion and a second non-pattern portion spaced apart in a second direction crossing the first direction with the pattern portion therebetween,
the upper surface comprises a (1-1)-th upper surface included in the first non-pattern portion, a (1-2)-th upper surface included in the second non-pattern portion, and second upper surfaces included in the pattern portion,
first inner surfaces of the substrate defining the first groove patterns comprise a (1-1)-th inner surface extending from the (1-1)-th upper surface, a (1-2)-th inner surface extending from the (1-2)-th upper surface, and a (1-3)-th inner surfaces extending from the second upper surfaces, and
the (1-1)-th and (1-2)-th inner surfaces each protrude further upward than the (1-3)-th inner surfaces.

8. The window of claim 7, wherein:
each of the first groove patterns provides first recessed spaces,
a plane to which a portion of the (1-1)-th inner surface protruding further than the (1-3)-th inner surface, a portion of the (1-2)-th inner surface protruding further than the (1-3)-th inner surfaces, and the second upper surfaces extend provides a second recessed space, and
the first recessed spaces and the second recessed space are formed as a single-body space.

9. The window of claim 7, wherein the second filling layer covers the second upper surfaces, at least a portion of the (1-1)-th inner surface protruding further than the (1-3)-th inner surfaces, and at least a portion of the (1-2)-th inner surface protruding further than the (1-3)-th inner surfaces.

10. The window of claim 1, wherein the first to fourth filling layers have a refractive index substantially equal to a refractive index of the substrate.

11. The window of claim 1, further comprising:
at least one additional filling layer disposed on the second filling layer and covering the second filling layer.

12. The window of claim 1, wherein:
each of the first groove patterns and the second groove patterns extends in a first direction,
the first groove patterns and the second groove patterns are alternately arranged in a second direction crossing the first direction, and
the substrate is folded or bent with respect to an imaginary axis extending in the first direction.

13. A display device comprising:
a display module including a folding region folded with respect to an imaginary axis extending in one direction and a non-folding region adjacent to the folding region; and
a window disposed on the display module,
wherein the window includes:
a substrate that includes an upper surface and a lower surface facing the upper surface, the substrate including a pattern portion including first groove patterns recessed from the upper surface and second groove patterns recessed from the lower surface and alternately arranged with the first groove patterns, and a non-pattern portion adjacent to the pattern portion;
first filling layers each disposed in a respective one of the first groove patterns;
a second filling layer covering the first filling layers;
third filling layers each disposed in a respective one of the second groove patterns; and
a fourth filling layer covering the third filling layers, wherein a height of the pattern portion is less than a height of the non-pattern portion.

14. The display device of claim 13, further comprising:
a protection film disposed below the display module; and
a support disposed below the protection film.

15. A method of manufacturing a window, the method comprising:
forming a first initial groove pattern recessed from an upper surface and a second initial groove pattern recessed from a lower surface on a mother substrate;
forming first groove patterns overlapping the first initial groove pattern and recessed from the upper surface, and second groove patterns overlapping the second initial groove pattern, recessed from the lower surface, and alternately arranged with the first groove patterns to form a substrate from the mother substrate;
forming first filling layers in the first groove patterns;
forming a second filling layer covering the first filling layers;
forming third filling layers in the second groove patterns; and
forming a fourth filling layer covering the third filling layers.

16. The method of claim 15, wherein:
in forming the first and second initial groove patterns, a first outer recessed space and a second outer recessed space are each provided by the first initial groove pattern and the second initial groove pattern,
in forming the first and second groove patterns, first inner recessed spaces and second inner recessed spaces are each provided by the first groove patterns and the second groove patterns,
the first filling layers are each filled in the first inner recessed spaces, and the second filling layer is filled in the first outer recessed space, and
the third filling layers are each filled in the second inner recessed spaces, and the fourth filling layer is filled in the second outer recessed space.

17. The method of claim 15, wherein:
forming the first filling layers comprises filling a first filling resin through an inkjet method, and
in filling the first filling resin, the first filling resin is provided at every position corresponding to the first groove patterns, and is provided in a range of about 70% to about 80% of a maximum width of the corresponding first groove pattern among the first groove patterns.

18. The method of claim 15, wherein forming the first filling layers comprises:
filling a first filling resin through an inkjet method; and
curing the filled first filling resin, wherein curing the filled first filling resin is performed after a predetermined period of time has passed after the filling of the first filling resin.

19. The method of claim 15, wherein:
forming the second filling layer comprises filling a second filling resin through an inkjet method, and
the second filling resin is continuously provided from one end of a first outer recessed space provided by the first initial groove pattern to another end of the first outer recessed space.

20. The method of claim 15, wherein each of the first and second initial groove patterns has a depth of about 14 μm to about 20 μm.

21. A window for a display device comprising:
a non-pattern portion in a non-folding region of the display device;
a pattern portion in a folding region of the display device and including:
a substrate having first grooves and second grooves arranged in an alternating pattern, the first grooves oriented in a first direction and the second grooves oriented in the first direction, wherein a thickness of the substrate in the pattern portion is less than a thickness of the substrate in the non-pattern portion.

22. The window of claim 21, wherein an upper surface of the substrate in the pattern portion is recessed relative to an upper surface of the non-pattern portion.

23. The window of claim 21, wherein a lower surface of the substrate in the pattern portion is recessed relative to a lower surface of the non-pattern portion.

24. The window of claim 21, wherein the pattern portion comprises:
first filling layers disposed in the first grooves;
a second filling layer disposed over the first filling layers;
third filling layers disposed in the second grooves; and
a fourth filling layer covering the third filling layers.

25. The window of claim 24, wherein:
upper surfaces of the first filling layers are at a lower height than an upper surface of the non-pattern portion.

26. The window of claim 24, wherein an upper surface of the second filling layer and an upper surface of the non-pattern portion are substantially coplanar.

27. The window of claim 26, wherein a lower surface of the fourth filling layer and a lower surface of the non-pattern portion are substantially coplanar.

28. The window of claim 24, wherein the first through fourth filling layers have a same refractive index as the substrate.
